(19) United States
(12) Patent Application Publication
(10) Pub. No.: US 2023/0139541 A1
(43) Pub. Date: May 4, 2023

(54) SEMICONDUCTOR DEVICE AND DATA STORAGE SYSTEM INCLUDING THE SAME

(71) Applicant: SAMSUNG ELECTRONICS CO., LTD., Suwon-si (KR)

(72) Inventors: Bongyong LEE, Suwon-si (KR); Seungwon LEE, Hwaseong-si (KR)

(21) Appl. No.: 17/969,942

(22) Filed: Oct. 20, 2022

(30) Foreign Application Priority Data
Oct. 29, 2021 (KR) 10-2021-0146505

(51) Int. Cl. H01L 27/11582; H01L 25/065; H01L 25/18; H01L 23/00

(52) U.S. Cl. CPC H01L 27/11582; H01L 24/08; H01L 25/18; H01L 25/0657; H01L 2224/08145; H01L 2924/1431; H01L 2924/14511

(57) ABSTRACT

A semiconductor device includes a substrate; a stack structure including a first gate layer, a first interlayer insulating layer, and a second gate layer; and a channel structure penetrating through the stack structure and in contact with the substrate, the channel structure including a channel layer, a vertical tunneling layer surrounding the channel layer, a charge storage pattern on an outer surface of the vertical tunneling layer, and a blocking pattern on an outer surface of the charge storage pattern, the charge storage pattern includes first and second charge storage material layers vertically spaced apart and adjacent to the gate layers, the blocking pattern includes vertically spaced blocking material layers between the charge storage material layers and the gate layers, and the blocking pattern contacts the outer surface of the charge storage pattern and includes a vertical protrusion extending longer than the outer surface of the charge storage pattern.

### CROSS-REFERENCE TO RELATED APPLICATION

This application claims the benefit under 35 USC 119(a) of Korean Patent Application No. 10-2021-0146505 filed on Oct. 29, 2021, in the Korean Intellectual Property Office, the entire disclosure of which is incorporated herein by reference for all purposes.

### BACKGROUND

### 1. Field

Embodiments relate to a semiconductor device and a data storage system including the same.

### 2. Description of the Related Art

In a data storage system, a semiconductor device capable of storing high-capacity data may be used.

### SUMMARY

The embodiments may be realized by providing a semiconductor device including a lower structure including a substrate; a stack structure including a first gate layer, a first interlayer insulating layer, and a second gate layer sequentially stacked on the lower structure; and a channel structure penetrating through the stack structure and in contact with the lower structure, the channel structure including a channel layer, a vertical tunneling layer surrounding the channel layer, a charge storage pattern on an outer side surface of the vertical tunneling layer, and a blocking pattern on an outer side surface of the charge storage pattern, wherein the charge storage pattern includes a first charge storage material layer and a second charge storage material layer spaced apart from each other in a vertical direction of an upper surface of the substrate and adjacent to the first gate layer and the second gate layer, respectively, the blocking pattern includes a first blocking material layer between the first charge storage material layer and the first gate layer and a second blocking material layer spaced apart from the first blocking material layer in the vertical direction and between the second charge storage material layer and the second gate layer, and the blocking pattern is in contact with the outer side surface of the charge storage pattern and includes a vertical protrusion part extending longer than the outer side surface of the charge storage pattern in the vertical direction.

The embodiments may be realized by providing a semiconductor device including a substrate; gate layers stacked on the substrate, the gate layers being spaced apart from each other in a vertical direction of an upper surface of the substrate; and channel structures penetrating through the gate layers and extending in the vertical direction, the channel structures respectively including a channel layer and a channel dielectric layer covering an outer side surface and a lower surface of the channel layer, wherein the channel dielectric layer includes a vertical tunneling layer, a charge storage pattern, and a blocking pattern sequentially stacked on the outer side surface and the lower surface of the channel layer, the charge storage pattern includes a first charge storage material layer and a second charge storage material layer on an outer side surface of the vertical tunneling layer and spaced apart from each other in the vertical direction, each of the first and second charge storage material layers including a first side surface in contact with the outer side surface of the vertical tunneling layer and a second side surface opposing the first side surface, the blocking pattern includes a first blocking material layer on the second side surface of the first charge storage material layer and a second blocking material layer spaced apart from the first blocking material layer in the vertical direction and on the second surface of the second charge storage material layer, each of the first and second blocking material layers includes a third side surface in contact with the charge storage pattern and a fourth side surface opposing the third side surface, a first length of the first side surface in the vertical direction is greater than a thickness, in the vertical direction, of each of the gate layers, and a second length of the second side surface in the vertical direction and a third length of the third side surface in the vertical direction are different from each other.

The embodiments may be realized by providing a data storage system including a semiconductor storage device including a lower structure including a lower substrate, circuit elements on the lower substrate, and an upper substrate on the circuit elements; a stack structure including a first gate layer, a first interlayer insulating layer, and a second gate layer sequentially stacked on the lower structure; a channel structure penetrating through the stack structure and in contact with the lower structure, and including a channel layer, a vertical tunneling layer surrounding the channel layer, an charge storage pattern on an outer side surface of the vertical tunneling layer, and a blocking pattern on an outer side surface of the charge storage pattern; and an input/output pad electrically connected to the circuit elements, the charge storage pattern including first and second charge storage material layers spaced apart from each other in a vertical direction of an upper surface of the lower structure and adjacent to the first and second gate layers, respectively, the blocking pattern including a first blocking material layer in contact with the first charge storage material layer and the first gate layer and a second blocking material layer spaced apart from the first blocking material layer in the vertical direction and in contact with the second charge storage material layer and the second gate layer, and the blocking pattern being in contact with the outer side surface of the charge storage pattern and including vertical protrusion part extending to be longer than the outer side surface of the charge storage pattern in the vertical direction; and a controller electrically connected to the semiconductor storage device through the input/output pads and controlling the semiconductor storage device.

The embodiments may be realized by providing a method of manufacturing a semiconductor device, the method including forming a molded structure including first material layers and second material layers, the first material layers being stacked on a substrate so as to be spaced apart from the substrate in a vertical direction and each having a first thickness, and the second material layers being stacked alternately with the first material layers and each having a second thickness; forming a hole penetrating through the molded structure and sequentially forming a preliminary blocking pattern, a preliminary charge storage pattern, a vertical tunneling layer, and a channel layer in the hole; forming trenches through the molded structure; forming first tunnel parts by selectively removing the second material layers with respect to the first material layers through the trenches; forming a blocking pattern by removing at least a portion of the preliminary blocking pattern exposed through the first tunnel parts; and forming a charge storage pattern including a plurality of charge storage material layers by removing at least a portion of the preliminary charge storage pattern exposed by the removed preliminary blocking pattern, wherein forming the charge storage pattern includes removing portions of the first material layers together with the preliminary charge storage pattern, and a third thickness of each of the first material layers removed in the vertical direction is smaller than the first thickness and is smaller than a length of each of the plurality of charge storage material layers in the vertical direction.

### BRIEF DESCRIPTION OF THE DRAWINGS

Features will be apparent to those of skill in the art by describing in detail exemplary embodiments with reference to the attached drawings in which:

FIG. 1 is a plan view of a semiconductor device according to example embodiments;

FIG. 2 is a cross-sectional view of the semiconductor device according to example embodiments;

FIGS. 3A to 3E are partially enlarged cross-sectional views of various examples of the semiconductor device according to example embodiments;

FIG. 4 is a cross-sectional view of a semiconductor device according to example embodiments;

FIG. 5 is a cross-sectional view of a semiconductor device according to example embodiments;

FIG. 6 is a cross-sectional view of a semiconductor device according to example embodiments;

FIG. 7 is a cross-sectional view of a semiconductor device according to example embodiments;

FIG. 8 is a schematic block diagram of a data storage system including a semiconductor device according to example embodiments;

FIG. 9 is a schematic perspective view of a data storage system including a semiconductor device according to an example embodiment;

FIG. 10 is a schematic cross-sectional view of a semiconductor package according to an example embodiment;

FIG. 11 is a flowchart of a process sequence of a method of manufacturing a semiconductor device according to example embodiments; and

FIG. 12A to 16 are cross-sectional views of stages in a method of manufacturing a semiconductor device according to example embodiments.

### DETAILED DESCRIPTION

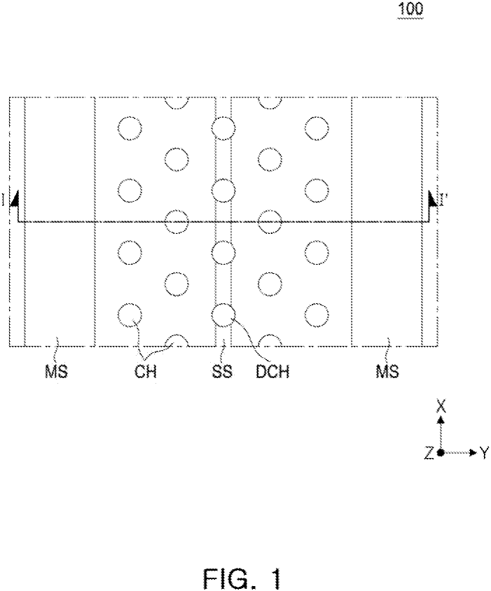

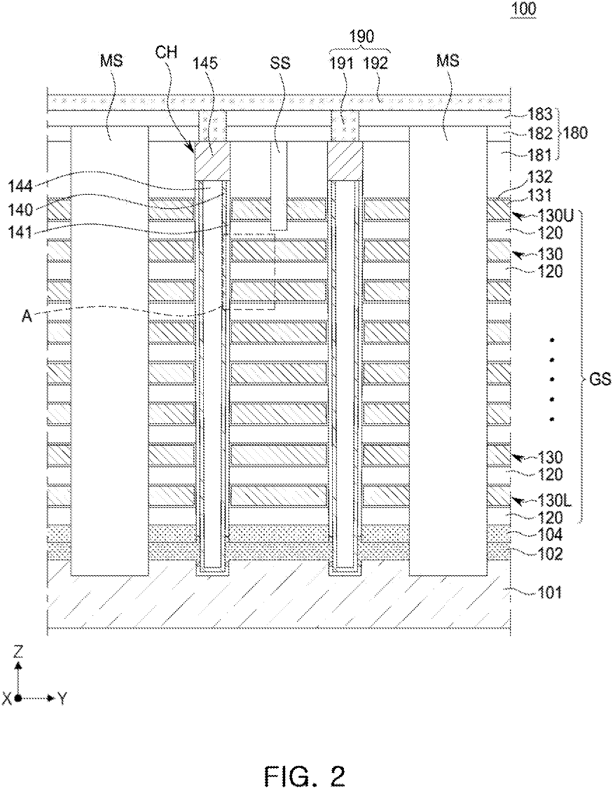

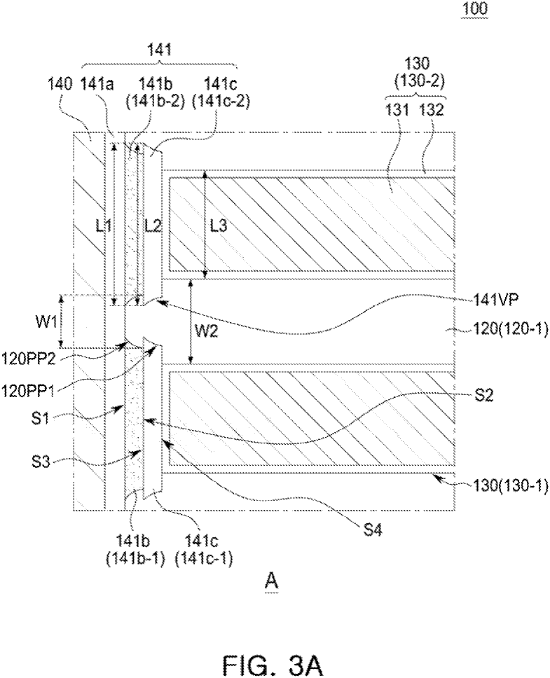

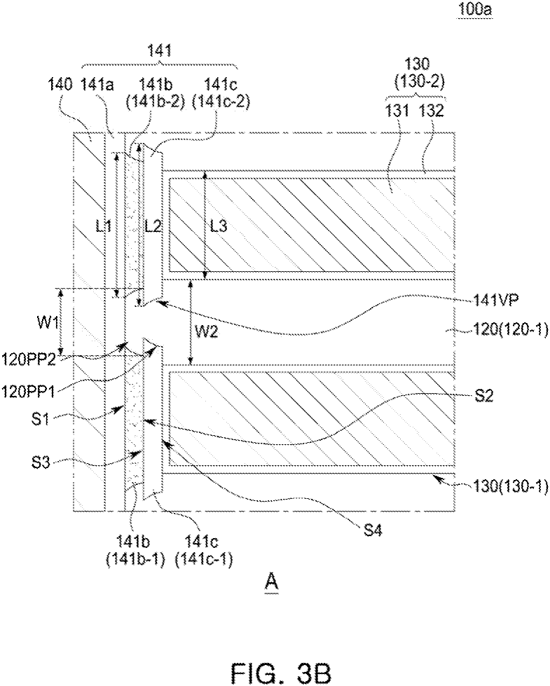

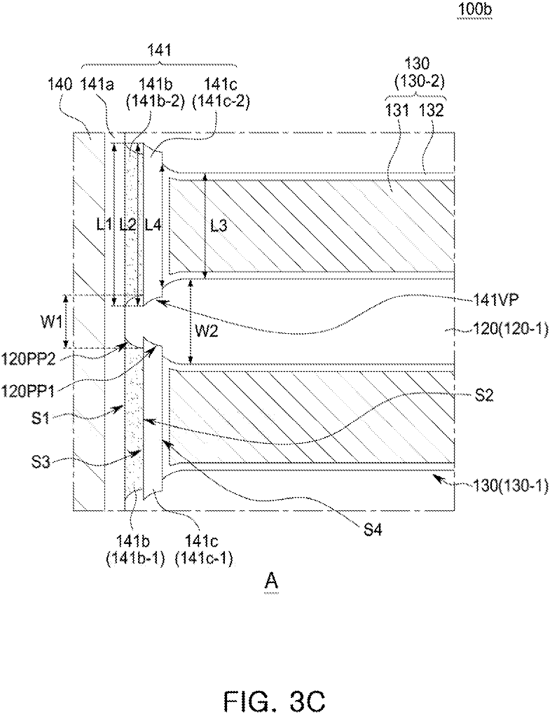

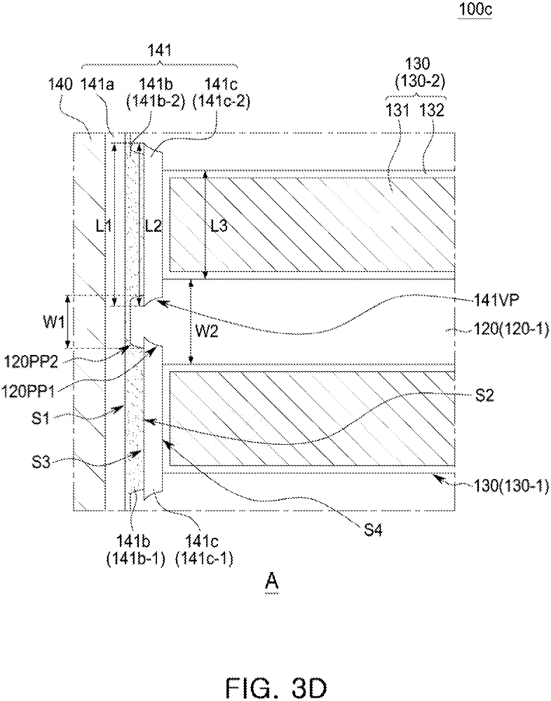

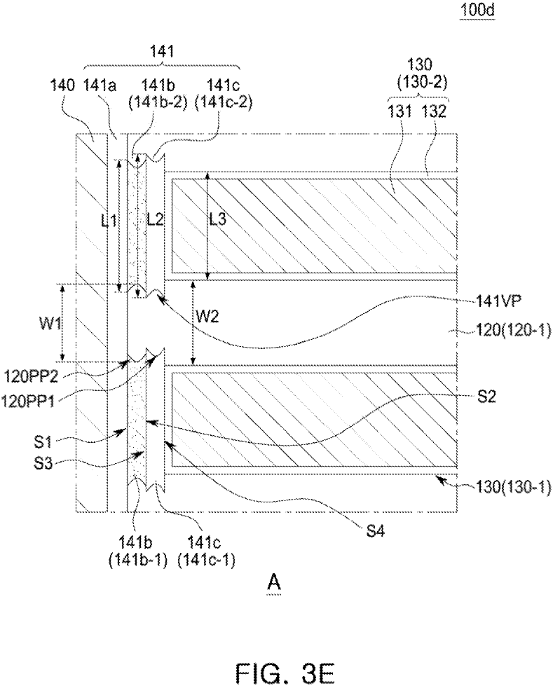

FIG. 1 is a plan view of a semiconductor device 100 according to example embodiments, and FIG. 2 is a cross-sectional view of the semiconductor device 100 according to example embodiments. FIG. 2 is a cross-sectional view of the semiconductor device 100 taken along line I-I′ of FIG. 1. FIG. 3A is a partially enlarged view of a region corresponding to region ‘A’ of the semiconductor device 100 of FIG. 2.

Referring to FIGS. 1 to 3A, the semiconductor device 100 may include a substrate 101, a first horizontal conductive layer 102, a second horizontal conductive layer 104, gate layers 130 stacked on the substrate 101, interlayer insulating layers 120 stacked alternately with the gate layers 130 on the substrate 101, isolation structures MS extending and penetrating through a stack structure GS including the gate layers 130 and the interlayer insulating layers 120, channel structures CH penetrating through the stack structure GS and respectively including a channel layer 140, and an upper insulating layer 180.

The substrate 101 may have an upper surface extending in an X-direction and a Y-direction (e.g., in an X-Y plane). The substrate 101 may include a semiconductor material, e.g., a group IV semiconductor, a group III-V compound semiconductor, or a group II-VI compound semiconductor. In an implementation, the group IV semiconductor may include, e.g., silicon, germanium, or silicon-germanium. In an implementation, the substrate 101 may be, e.g., a bulk wafer, an epitaxial layer, a silicon on insulator (SOI) layer, a semiconductor on insulator (SeOI) layer, or the like. As used herein, the term “or” is not an exclusive term, e.g., “A or B” would include A, B, or A and B.

The first and second horizontal conductive layers 102 and 104 may be sequentially stacked on the upper surface of the substrate 101. The first horizontal conductive layer 102 may function as at least a portion of a common source line of the semiconductor device 100, e.g., may function as the common source line with the substrate 101. As illustrated in FIG. 2, the first horizontal conductive layer 102 may be in direct contact with and electrically connected to the channel layer 140 at a periphery of the channel layer 140. The first and second horizontal conductive layers 102 and 104 may include a semiconductor material, e.g., polycrystalline silicon. In an implementation, the first horizontal conductive layer 102 may be a layer doped with impurities of the same conductivity-type as the substrate 101, and the second horizontal conductive layer 104 may be a doped layer or a layer including impurities diffused from the first horizontal conductive layer 102.

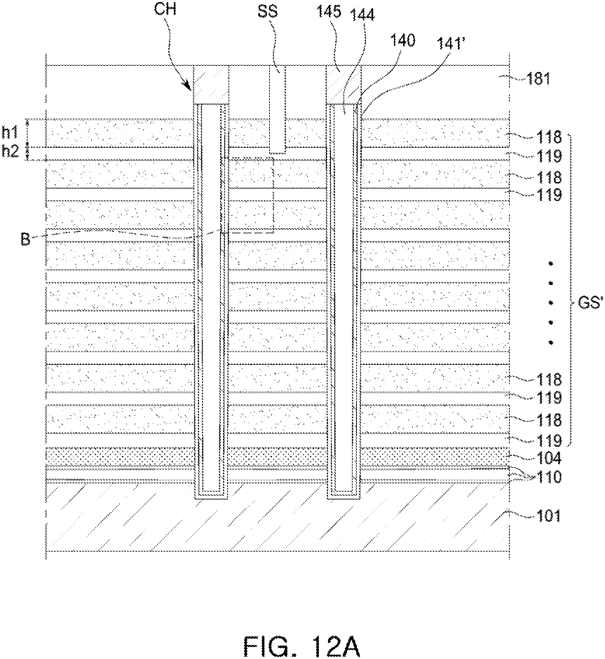

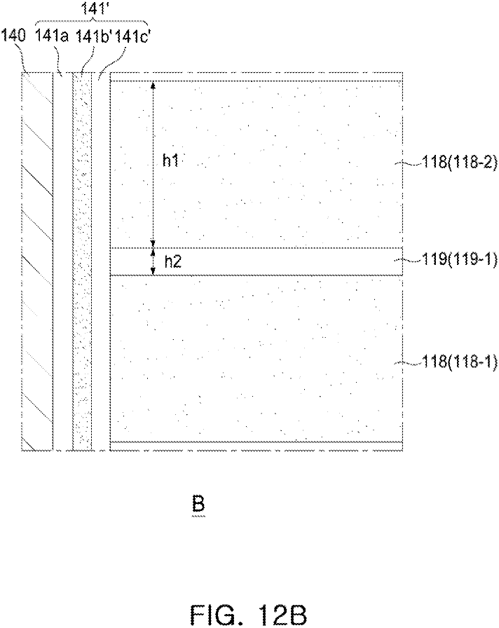

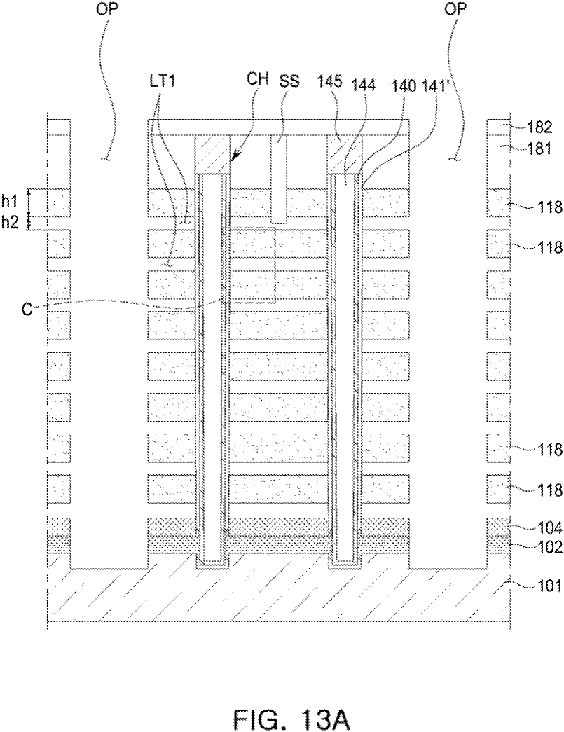

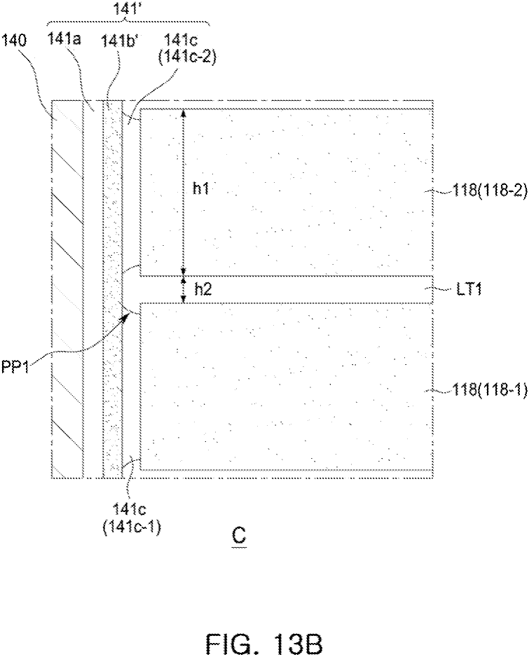

In an implementation, the semiconductor device 100 may further include horizontal insulating layers. The horizontal insulating layers may be spaced apart from the first horizontal conductive layer 102 and may be parallel to the first horizontal conductive layer 102 on the upper surface of the substrate 101. The horizontal insulating layers may be layers remaining after a portion thereof are replaced with the first horizontal conductive layer 102 in a process of manufacturing the semiconductor device 100. The second horizontal conductive layer 104 may cover the first horizontal conductive layer 102 and the horizontal insulating layers. The horizontal insulating layers may include first to third horizontal insulating layers that are sequentially stacked. The horizontal insulating layers may include, e.g., silicon oxide, silicon nitride, silicon carbide, or silicon oxynitride. The first and third horizontal insulating layers may include an insulating material different from that of the second horizontal insulating layer. The first and third horizontal insulating layers may include the same material. In an implementation, the first and third horizontal insulating layers may be formed of the same material as the interlayer insulating layers 120, and the second horizontal insulating layer may be formed of the same material as sacrificial first material layers 118 (see FIG. 12A).

In an implementation, a lower structure may include the substrate 101, the first horizontal conductive layer 102, the second horizontal conductive layer 104, and the horizontal insulating layers. In an implementation, the lower structure may not include the first and second horizontal conductive layers 102 and 104 and the horizontal insulating layers.

The gate layers 130 may be stacked on the lower structure and spaced apart from an upper surface of the lower structure in a Z-direction, which is a vertical direction, to constitute the stack structure GS. The gate layers 130 may be stacked to be vertically spaced apart from each other on a first region of the substrate 101, and may extend at different lengths from the first region to a second region of the substrate 101 to form a step structure having a stair shape. The first region may correspond to a memory array region, and the second region may be a region for electrical connection with word lines of the memory array region. The first region may be referred to as a ‘memory cell region’ or a ‘memory cell array region,’ and the second region may be referred to as a ‘stair region’ or a ‘connection region.’ In an implementation, at least some of the gate layers 130, e.g., a predetermined number of gate layers 130 such as two to six gate layers 130, may constitute one gate group, and a step structure may be formed between the gate groups along the X-direction.

The gate layers 130 may include a lower gate electrode including a gate of a ground select transistor, middle gate electrodes constituting gates of a plurality of memory cells, and an upper gate electrode including gates of a string select transistor. The lower gate electrode may be a ground selection line, the upper gate electrode may be a string selection line, and the middle gate electrodes may be word lines. The number of middle gate electrodes constituting the plurality of memory cells may be determined according to a capacity of the semiconductor device 100. In an implementation, each of the numbers of upper and lower gate electrodes may be one or two or more, and the upper and lower gate electrodes may have structures that are the same as or different from those of the middle gate electrodes. In an implementation, the gate layers 130 may further include a gate electrode above the upper gate electrode or below the lower gate electrode and constituting an erase transistor used for an erase operation using a gate induced drain leakage (GIDL) phenomenon. In addition, some of the gate layers 130, e.g., the middle gate electrodes adjacent to the upper or lower gate electrodes may be dummy gate electrodes.

In an implementation, each of the gate layers 130 may include a gate conductive layer 131 and a gate dielectric layer 132. The gate conductive layer 131 may be a gate electrode. The gate dielectric layer 132 may cover side surfaces of the gate conductive layer 131 facing the channel structures CH while covering upper and lower surfaces of the gate conductive layer 131. Accordingly, the gate dielectric layer 132 may extend between the gate conductive layer 131 and the interlayer insulating layers 120 while being between the gate conductive layer 131 and the channel structures CH. The gate conductive layer 131 may include a conductive material such as tungsten (W). In an implementation, the gate conductive layer 131 may include polycrystalline silicon or a metal silicide material. The gate dielectric layer 132 may be formed of a dielectric material, and may include, e.g., aluminum oxide (AlO). The gate dielectric layer 132 may serve as a blocking layer for preventing electrical charges in a charge storage pattern 141b from moving to the gate conductive layer 131, together with a blocking pattern 141c. In an implementation, the semiconductor device 100 may include a diffusion barrier surrounding the gate conductive layer 131 unlike the gate dielectric layer 132. The diffusion barrier may include, e.g., silicon nitride, tungsten nitride (WN), tantalum nitride (TaN), titanium nitride (TiN), or combinations thereof. In an implementation, the gate layers 130 of the semiconductor device 100 may include all of the gate conductive layer, the diffusion barrier, and the gate dielectric layer surrounding the diffusion barrier.

The interlayer insulating layers 120 may be between the gate layers 130. The interlayer insulating layers 120 may be stacked alternately with the gate layers 130 to constitute the stack structure GS. The interlayer insulating layers 120 may include an insulating material such as silicon oxide or silicon nitride.

In an implementation, the gate layers 130 may include a first gate layer 130-1 and a second gate layer 130-2 adjacent to each other, and the interlayer insulating layers 120 may include a first interlayer insulating layer 120-1 (e.g., on a level) between the first gate layer 130-1 and the second gate layer 130-2. Accordingly, the stack structure GS may include the first gate layer 130-1, the first interlayer insulating layer 120-1, and the second gate layer 130-2 that are sequentially stacked.

The isolation structures MS may penetrate through the gate layers 130, the interlayer insulating layers 120, and the first and second horizontal conductive layers 102 and 104 and may be connected to the substrate 101. In an implementation, the isolation structures MS may extend into the substrate 101 to be in contact with the substrate 101, or may be in contact with the upper surface of the substrate 101 without penetrating through the substrate 101, or may be spaced apart from the substrate 101. In an implementation, the isolation structures MS may have a shape of which a width (e.g., as measured in the X direction or Y direction) decreases toward or closer to the substrate 101 due to a high aspect ratio. The isolation structures MS may be respectively positioned in trenches extending (e.g., lengthwise) along the X-direction. The isolation structures MS may be spaced apart from each other in the Y-direction. In an implementation, the isolation structures MS may isolate the gate layers 130 from each other along the Y-direction. In an implementation, the isolation structures MS may include a metal material or an insulating material in the trenches. In an implementation, each of the isolation structures MS may include an isolation pattern and spacers on side surfaces of the isolation pattern. The isolation pattern may include a conductive material, and the spacers may include an insulating material such as silicon oxide.

Upper isolation structures SS may extend in the X-direction between the isolation structures MS adjacent to each other in the Y-direction. The upper isolation structures SS may penetrate through some of the gate layers 130U, including the uppermost gate layer 130U of the gate layers 130. In an implementation, as illustrated in FIG. 2, the upper isolation structures SS may isolate, e.g., one gate layer 130U in the Y-direction, or the number of gate layers isolated by the upper isolation structures SS may be variously modified. The number of isolated gate layers 130 may be determined according to the number of string selection lines. The upper isolation structures SS may include an insulating material.

The channel structures CH may penetrate through the stack structure GS including the gate layers 130 and the interlayer insulating layers 120. In an implementation, the channel structures CH may penetrate through the first and second horizontal conductive layers 102 and 104 and extend into the substrate 101. The channel structures CH may each constitute one memory cell string, and may be spaced apart from each other while forming rows and columns on the substrate 101. The channel structures CH may form a lattice pattern in the X-Y plane or may be in a zigzag shape in one direction. The channel structures CH may have a hole shape and a pillar shape, and may have inclined side surfaces that become narrower as they become closer to the substrate 101, e.g., according to an aspect ratio. In an implementation, as illustrated in FIGS. 2 and 3A, each of the channel structures CH may further include a channel dielectric layer 141 surrounding the channel layer 140 and a channel pad 145 on an upper end of the channel layer 140, in addition to the channel layer 140. In an implementation, each of the channel structures CH may further include a channel filling insulating layer 144 covering inner side surfaces of the channel layer 140.

In an implementation, the channel layer 140 may have an annular shape surrounding the channel filling insulating layer 144 therein, or may have a pillar shape such as a cylindrical shape or a prismatic shape without the channel filling insulating layer 144. The channel layer 140 may be connected to the first horizontal conductive layer 102 at a lower portion thereof. The channel layer 140 may include a semiconductor material, e.g., polycrystalline silicon or single crystal silicon, and the semiconductor material may be an undoped material or a material including p-type or n-type impurities.

The channel dielectric layer 141 may include a vertical tunneling layer 141a covering an outer side surface of the channel layer 140, a charge storage pattern 141b on an outer side surface of the vertical tunneling layer 141a, and a blocking pattern 141c on an outer side surface of the charge storage pattern 141b. In a horizontal direction perpendicular to the Z-direction, (e.g., as measured in the X direction or Y direction) each of the vertical tunneling layer 141a, the charge storage pattern 141b, and the blocking pattern 141c may have a uniform thickness.

The vertical tunneling layer 141a may have an annular shape surrounding the channel layer 140. The vertical tunneling layer 141a may have a shape covering a side surface and a lower surface of the channel layer 140. Accordingly, an inner side surface of the vertical tunneling layer 141a may be in contact (e.g., direct contact) with the channel layer 140. The outer side surface of the vertical tunneling layer 141a may be in contact with the charge storage pattern 141b and the interlayer insulating layers 120. The vertical tunneling layer 141a may tunnel electrical charges of the channel layer 140 to the charge storage pattern 141b, and may include, e.g., silicon oxide (SiO₂), silicon nitride (Si₃N₄), silicon oxynitride (SiON), or combinations thereof.

The charge storage pattern 141b may be on the outer side surface of the vertical tunneling layer 141a. The charge storage pattern 141b may be between the vertical tunneling layer 141a and the blocking pattern 141c. The charge storage pattern 141b may have a uniform thickness and may surround the vertical tunneling layer 141a. In an implementation, an upper surface and a lower surface of the charge storage pattern 141b may be curved surfaces. The charge storage pattern 141b may be a charge trap layer. In an implementation, the charge storage pattern 141b may trap and retain electrons injected from the channel layer 140 through the vertical tunneling layer 141a into the charge trap layer or erase electrons trapped in the charge trap layer, according to operation conditions of a nonvolatile memory element such as a flash memory element. The charge storage pattern 141b may include a plurality of charge storage material layers spaced apart from each other in the Z-direction. The plurality of charge storage material layers may be electrically isolated from each other by the interlayer insulating layers 120. The plurality of charge storage material layers may be spaced apart from each other, and thus, an electrical charge loss problem that could otherwise occur in the Z-direction may be addressed.

In an implementation, the plurality of charge storage material layers may include a first charge storage material layer 141b-1 and a second charge storage material layer 141b-2 adjacent to each other in the Z-direction. A maximum length L1 of each of the first and second charge storage material layers 141b-1 and 141b-2 in the Z-direction may be greater than a maximum length L3 of each of the first and second gate layers 130-1 and 130-2 in the Z-direction. This may be because the charge storage pattern 141b includes a material of which an etch rate may be controlled to be slower than that of first material layers 118 (see FIG. 12A) in a region corresponding to the gate layers 130 under a specific etching condition. In an implementation, the maximum length L3 of each of the first and second gate layers 130-1 and 130-2 in the Z-direction may refer to a maximum length of the gate conductive layer 131 in the Z-direction. In the horizontal direction perpendicular to the Z-direction, e.g., the Y-direction the first and second gate layers 130-1 and 130-2 may overlap the first and second charge storage material layers 141b-1 and 141b-2, respectively. Accordingly, an electrical charge loss problem that could otherwise occur in the horizontal direction may be addressed.

The charge storage pattern 141b may include, e.g., a nitride, a silicon nitride, or a nitride material. The charge storage pattern 141b may include a material having an etch rate lower than that of the first material layer 118 (see FIG. 12A) under a specific etching condition. The charge storage pattern 141b and the first material layer 118 may be layers etched in the same etching process. In an implementation, the charge storage pattern 141b may include the same material as the first material layer 118, or may have a composition ratio different from that of the first material layer 118.

The blocking pattern 141c may be between the charge storage pattern 141b and the gate layers 130. The blocking pattern 141c may have a uniform thickness (e.g., as measured in the X direction or Y direction) on the outer side surface of the charge storage pattern 141b. In an implementation, an upper surface and a lower surface of the blocking pattern 141c may be curved surfaces. The blocking pattern 141c may be a blocking layer that helps prevent the electrical charges trapped in the charge storage pattern 141b from moving to the gate layers 130. In an implementation, the blocking layer may include the charge storage pattern 141b and the gate dielectric layer 132. In an implementation, the blocking pattern 141c may include a plurality of blocking material layers spaced apart from each other in the Z-direction.

In an implementation, the plurality of blocking material layers may include a first blocking material layer 141c-1 and a second blocking material layer 141c-2 adjacent to each other in the Z-direction. The first blocking material layer 141c-1 may be between the first charge storage material layer 141b-1 and the first gate layer 130-1, and the second blocking material layer 141c-2 may be between the second charge storage material layer 141b-2 and the second gate layer 130-2. The first blocking material layer 141c-1 may be in contact with the first charge storage material layer 141b-1 and the first gate layer 130-1, and the second blocking material layer 141c-2 may be in contact with the second charge storage material layer 141b-2 and the second gate layer 130-2. A maximum length L2 of each of the first and second blocking material layers 141c-1 and 141c-2 in the Z-direction may be greater than the maximum length L3 of each of the first and second gate layers 130-1 and 130-2 in the Z-direction. In the horizontal direction perpendicular to the Z-direction, the first and second gate layers 130-1 and 130-2 may overlap the first and second blocking material layers 141c-1, 141c-2, respectively. In an implementation, the maximum length L2 of each of the first and second blocking material layers 141c-1 and 141c-2 in the Z-direction may be substantially the same as the maximum length L1 of each of the first and second charge storage material layers 141b-1 and 141b-2 in the Z-direction, or may be smaller than the maximum length L1 of each of the first and second charge storage material layers 141b-1 and 141b-2 in the Z-direction.

The blocking pattern 141c may include, e.g., silicon oxide (SiO₂), silicon nitride (Si₃N₄), silicon oxynitride (SiON), a high-k dielectric material, or combinations thereof.

In an implementation, each of the first and second charge storage material layers 141b-1 and 141b-2 may include a first side surface S1 in contact with the outer side surface of the vertical tunneling layer 141a and a second side surface S2, which is an outer side surface opposing the first side surface S1. A first length of the first side surface S1 in the Z-direction may be greater than a second length of the second side surface S2 in the Z-direction. The first length may be greater than a thickness of each of the gate layers 130. Each of the first and second blocking material layers 141c-1 and 141c-2 may include a third side surface S3 in contact with the charge storage pattern 141b and a fourth side surface S4 being an outer side surface opposing the third side surface S3 and in contact with the gate layers 130. A third length of the third side surface S3 in the Z-direction may be greater than a fourth length of the fourth side surface S4 in the Z-direction. The second length of the second side surface S2 may be smaller than the third length of the third side surface S3. In an implementation, the blocking pattern 141c may further include vertical protrusion parts 141VP extending in the Z-direction from a surface thereof in contact with the charge storage pattern 141b. Accordingly, the channel dielectric layer 141 may include steps (e.g., discontinuities or level differences) between the charge storage pattern 141b and the blocking pattern 141c. The vertical protrusion parts 141VP or the steps may be structures generated while performing an etching process for the blocking pattern 141c and an etching process for the charge storage pattern 141b in two steps. The blocking pattern 141c may be in contact with the outer side surface of the charge storage pattern 141b, and the vertical protrusion parts 141VP may extend to be longer than the outer side surface of the charge storage pattern 141b in the Z-direction.

In an implementation, the first gate layer 130-1 may be in contact with the first blocking material layer 141c-1, the second gate layer 130-2 may be in contact with the second blocking material layer 141c-2, and the first interlayer insulating layer 120-1 may be (e.g., on or at the level) between the first gate layer 130-1 and the second gate layer 130-2. The first interlayer insulating layer 120-1 may extend between the first gate layer 130-1 and the second gate layer 130-2 to cover the first and second blocking material layers 141c-1 and 141c-2 and the first and second charge storage material layers 141b-1 and 141b-2, and may be in contact with the vertical tunneling layer 141a.

The first interlayer insulating layer 120-1 may include a first horizontal protrusion part 120PP1 extending in a direction toward the vertical tunneling layer 141a and a second horizontal protrusion part 120PP2 extending in a direction from the first horizontal protrusion part 120PP1 toward the vertical tunneling layer 141a. The first horizontal protrusion part 120PP1 may isolate the first blocking material layer 141c-1 and the second blocking material layer 141c-2 from each other, and the second horizontal protrusion part 120PP2 may isolate the first charge storage material layer 141b-1 and the second charge storage material layer 141b-2 from each other. Each of the first and second horizontal protrusion parts 120PP1 and 120PP2 may have a convex shape in the direction toward the vertical tunneling layer 141a. In the first interlayer insulating layer 120-1, a first thickness W1 of the second horizontal protrusion part 120PP2 (as measured in the Z direction) may be smaller than a second thickness W2 in a region between the first gate layer 130-1 and the second gate layer 130-2 (as measured in the Z direction). In an implementation, a distance (in the Z direction) between the first and second charge storage material layers 141b-1 and 141b-2 spaced apart from each other may be smaller than a distance (in the Z direction) between the first and second gate layers 130-1 and 130-2 spaced apart from each other. This may be because the charge storage pattern 141b may include a material of which an etch rate may be controlled to be slower than that of the first material layers 118 (see FIG. 12A) in the region corresponding to the gate layers 130 under a specific etching condition, e.g., a material different from that of the first material layers 118 (see FIG. 12A). At least portions of the vertical protrusion parts 141VP of the first and second blocking material layers 141c-1 and 141c-2 may be in contact with the first horizontal protrusion part 120PP1 and the second horizontal protrusion part 120PP2.

The channel pad 145 may be on the channel layer 140 in each of the channel structures CH. The channel pad 145 may cover an upper surface of the channel filling insulating layer 144 and may be electrically connected to the channel layer 140. The channel pad 145 may include, e.g., doped polycrystalline silicon.

In an implementation, the semiconductor device 100 may further include dummy channel structures DCH having the same structure as the channel structures CH. The dummy channel structures DCH may be spaced apart from each other while forming rows and columns with the channel structures CH on the substrate 101, and may be, e.g., in a region overlapping the upper isolation structures SS. In an implementation, the dummy channel structures DCH may penetrate through the gate layers 130 and the upper isolation structures SS, or an arrangement relationship and structure of the dummy channel structures DCH may be variously modified.

The upper insulating layer 180 may cover the stack structure GS including the gate layers 130 and the interlayer insulating layers 120 and the channel structures CH. The upper insulating layer 180 may be formed of an insulating material, and may include, e.g., silicon oxide, silicon nitride, or silicon oxynitride. In an implementation, the upper insulating layer 180 may include a first upper insulating layer 181, a second upper insulating layer 182 on the first upper insulating layer 181, and a third upper insulating layer 183 on the second upper insulating layer 182. The first upper insulating layer 181 may cover the stack structure GS, the second upper insulating layer 182 may cover the channel structures CH, the dummy channel structures DCH, and the first upper insulating layer 181, and the third upper insulating layer 183 may cover the isolation structures MS and the second upper insulating layer 182. The isolation structures MS may penetrate through the second upper insulating layer 182 and have an upper surface coplanar with an upper surface of the third upper insulating layer 183.

In an implementation, the semiconductor device 100 may further include an upper wiring structure 190 including upper contact structures 191 and an upper wiring pattern 192. The upper contact structures 191 may penetrate through the second and third upper insulating layers 182 and 183 and be connected to the channel structures CH. The upper contact structures 191 may include a conductive material, e.g., tungsten (W), copper (Cu), or aluminum (Al). The upper wiring pattern 192 may be on the third upper insulating layer 183, and may constitute an upper wiring structure electrically connected to the channel structures CH. The upper wiring pattern 192 may be bit lines. The upper wiring pattern 192 may include a conductive material, e.g., tungsten (W), copper (Cu), or aluminum (Al). In an implementation, the upper contact structures 191 and the upper wiring pattern 192 may include the same material. In an implementation, the upper wiring pattern 192 and the upper contact structures 191 may be formed by different processes, or may be formed integrally with each other.

FIG. 3B is a partially enlarged cross-sectional view of a modified example of a semiconductor device 100a according to example embodiments. FIG. 3B is a partially enlarged view illustrating a region corresponding to region ‘A’ of FIG. 2.

Referring to FIG. 3B, the maximum length L2 of the first blocking material layer 141c-1 in the Z-direction may be greater than the maximum length L1 of the first charge storage material layers 141b-1 in the Z-direction and the maximum length L3 of the first gate layers 130-1 in the Z-direction. This may be a structure generated because an etch rate difference of the charge storage pattern 141b and a first material layer 118 (see FIG. 12A) in a region corresponding to the first gate layer 130-1 may be relatively small as compared with an example embodiment of FIG. 3A. The first charge storage material layer 141b-1 may include a material of which an etch rate is slower than that of the first material layers 118 under a specific etching condition. In an implementation, in a process of etching portions of the first material layers 118 to make a region corresponding to the maximum length L3 of the first gate layer 130-1 in the Z-direction remain, an etch rate for the first charge storage material layer 141b-1 may relatively increase as compared with an example embodiment of FIG. 3A, such that the maximum length of the first charge storage material layer 141b-1 in the Z-direction may decrease.

In an implementation, each of the first and second charge storage material layers 141b-1 and 141b-2 may include a first side surface S1 in contact with the outer side surface of the vertical tunneling layer 141a and a second side surface S2, which is an outer side surface opposing the first side surface S1. A first length of the first side surface S1 in the Z-direction may be greater than a second length of the second side surface S2 in the Z-direction. The first length may be greater than a thickness (in the Z direction) of each of the gate layers 130. Each of the first and second blocking material layers 141c-1 and 141c-2 may include a third side surface S3 in contact with the charge storage pattern 141b-1 and a fourth side surface S4 being an outer side surface opposing the third side surface S3 and in contact with the gate layers 130. A third length of the third side surface S3 in the Z-direction may be greater than a fourth length of the fourth side surface S4 in the Z-direction. The second length of the second side surface S2 may be smaller than the third length of the third side surface S3. The first length of the first side surface S1 may be smaller than the third length or the fourth length.

In an implementation, in the first interlayer insulating layer 120-1, a first thickness W1 of the second horizontal protrusion part 120PP2 may be smaller than a second thickness W2 in a region between the first gate layer 130-1 and the second gate layer 130-2. In addition, the first thickness W1 may be greater than a thickness of the first horizontal protrusion part 120PP1 in the Z-direction.

The second charge storage material layer 141b-2 may have the same structure as the first charge storage material layer 141b-1, the second blocking pattern 141c-2 may have the same structure as the first blocking pattern 141c-1, the second gate layer 130-2 may have the same structure as the first gate layer 130-1, and a repeated description may be omitted.

FIG. 3C is a partially enlarged cross-sectional view of a modified example of a semiconductor device 100b according to example embodiments. FIG. 3C is a partially enlarged view illustrating a region corresponding to region ‘A’ of FIG. 2.

Referring to FIG. 3C, the semiconductor device 100b may include the same structure as the semiconductor device 100 of FIG. 3A except for a structure of the gate layers 130.

In the gate layers 130, a thickness L4 (in the Z direction) of a region in contact with the blocking pattern 141c may be greater than a thickness L3 of the other regions (e.g., distal to the blocking pattern 141). The gate layers 130 may have a uniform thickness in the other regions and may have an increasing thickness toward the blocking pattern 141c in the region in contact with or adjacent to the blocking pattern 141c. This may be caused by the first material layers 118 that are not etched to have a uniform thickness and remain in a process of etching the first material layers 118 (see FIG. 12A) in regions corresponding to the gate layers 130.

FIG. 3D is a partially enlarged cross-sectional view of a modified example of a semiconductor device 100c according to example embodiments. FIG. 3D is a partially enlarged view of a region corresponding to region ‘A’ of FIG. 2.

Referring to FIG. 3D, the semiconductor device 100c may include the same structure as the semiconductor device 100 of FIG. 3A except for a structure of the charge storage pattern 141b.

The charge storage pattern 141b may be a charge storage material layer that continuously extends (e.g., along the entire height or length of the channel dielectric layer 141 in the Z direction). The charge storage material layer may not be a plurality of charge storage material layers spaced apart from each other, and may be a single charge storage material layer having a non-uniform thickness on the outer side surface of the vertical tunneling layer 141a. The charge storage material layer may have a relatively great thickness (e.g., in a horizontal direction) in a region in contact with the blocking pattern 141c and a relatively small thickness in a region in contact with the interlayer insulating layers 120. This may be a structure generated because in a process of forming an opening in a region corresponding to the second protrusion part 120PP2, the opening may not be formed so as to penetrate through the charge storage pattern 141b and may be in contact with the vertical tunneling layer 141a.

FIG. 3E is a partially enlarged cross-sectional view of a modified example of a semiconductor device 100d according to example embodiments. FIG. 3E is a partially enlarged view of a region corresponding to region ‘A’ of FIG. 2.

Referring to FIG. 3E, the semiconductor device 100d may include a structure of a charge storage pattern 141b different from that of FIG. 3A. The charge storage pattern 141b may have upper and lower surfaces convex toward an inner portion of the charge storage pattern 141b (e.g., may have inwardly recessed upper and lower surfaces) This may be a structure generated by using an etching process or an etching material different from that of FIG. 3A. However, also in this case, as described above with reference to FIG. 3A, the charge storage pattern 141b and the first material layers 118 (see FIG. 12A) may be etched in the same etching process, and the maximum length L1 of each of the first and second charge storage material layers 141b-1 and 141b-2 in the Z-direction may be greater than the maximum length L3 of each of the first and second gate layers 130-1 and 130-2 in the Z-direction.

In an implementation, the blocking pattern 141c may have upper and lower surfaces convex toward an inner portion of the blocking pattern 141c, similar to the charge storage pattern 141b. In an implementation, the blocking pattern 141c may include the upper and lower structures of FIG. 3A unlike the charge storage pattern 141b.

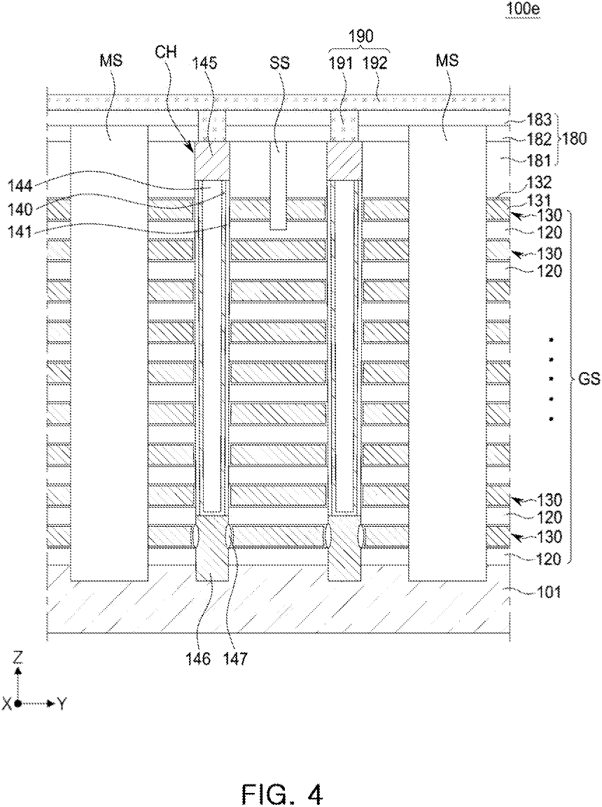

FIG. 4 is a cross-sectional view of a semiconductor device 100e according to example embodiments. FIG. 4 illustrates a region corresponding to a cross section of the semiconductor device 100e taken along line I-I′ of FIG. 1.

Referring to FIG. 4, the semiconductor device 100e may have structures of a lower structure and channel structures different from those of the semiconductor device 100 of FIG. 1 to 3A. Accordingly, a repeated description of structures similar to those described above with reference to FIG. 1 to 3A may be omitted.

The lower structure may include the substrate 101, and may not include the first horizontal conductive layer 102, the second horizontal conductive layer 104, and the horizontal insulating layers, unlike FIG. 2. The semiconductor device 100e may include the stack structure GS including the interlayer insulating layers 120 and the gate layers 130 spaced apart from each other and alternately stacked on the lower structure.

Each of the channel structures CH may further include a lower epitaxial layer 146 together with the channel layer 140, the vertical tunneling layer 141a, the charge storage pattern 141b, the blocking pattern 141c, the channel filling insulating layer 144, and the channel pad 145.

The lower epitaxial layer 146 may be on the upper surface of the substrate 101 at a lower end of each of the channel structures CH, and may be on a side surface of the at least one lower gate layer 130. The lower epitaxial layer 146 may be connected to the channel layer 140. The lower epitaxial layer 146 may be in a recessed region of the substrate 101. An insulating layer 147 may be between the lower epitaxial layer 146 and the lower gate layer 130. In an implementation, the lower epitaxial layer 146 may be omitted. In this case, the channel layer 140 may be directly connected to the substrate 101 or may be connected to a separate conductive layer on the substrate 101.

The channel layer 140 may cover a lower surface and side surfaces of the channel filling insulating layer 144, and may be in contact with an upper surface of the epitaxial layer 146 on the lower epitaxial layer 146. The vertical tunneling layer 141a may cover side surface of the channel layer 140. In an implementation, the vertical tunneling layer 141a may not cover a lower surface of the channel layer 140.

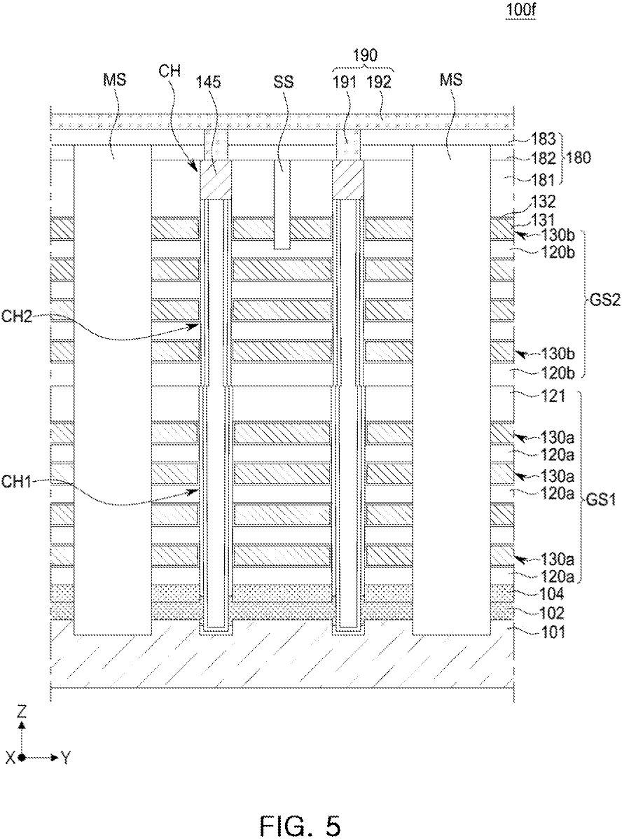

FIG. 5 is a cross-sectional view of a semiconductor device 100f according to example embodiments. FIG. 5 illustrates a region corresponding to a cross section of the semiconductor device 100f taken along line I-I′ of FIG. 1.

Referring to FIG. 5, in the semiconductor device 100f, the stack structure GS may include a lower stack structure GS1 and an upper stack structure GS2 on the lower stack structure GS1, and each of the channel structures CH may include a lower channel structure CH1 and an upper channel structure CH2 on the lower channel structure CH1. Such a structure of each of the channel structures CH may be introduced in order to stably form the channel structures CH when the number of stacked gate layers 130 is relatively large. In an implementation, the number of stacked channel structures may be variously modified.

The lower stack structure GS1 may include lower interlayer insulating layers 120a and lower gate layers 130a alternately stacked on the substrate 101, and the upper stack structure GS2 may include upper interlayer insulating layers 120b and upper gate layers 130b alternately stacked on the lower stack structure GS1. In an implementation, the lower stack structure GS1 may further include a connection insulating layer 121 at the uppermost end thereof and having a thickness (in the Z direction) relatively greater than that of the interlayer insulating layers 120. The connection insulating layer 121 may include an insulating material, e.g., silicon oxide, silicon nitride, or silicon oxynitride. The connection insulating layer 121 may include the same material as the interlayer insulating layers 120.

Each of the channel structures CH may include the lower channel structure CH1 penetrating through the lower stack structure GS1 and the upper channel structure CH2 penetrating through the upper stack structure GS2. The upper channel structure CH2 may penetrate through the upper stack structure GS2 and be connected to the lower channel structure CH1. In an implementation, the lower channel structure CH1 and the upper channel structure CH2 may have a connected form. The channel layer 140, the vertical tunneling layer 141, and the channel filling insulating layer 144 may have a connected form between the lower channel structure CH1 and the upper channel structure CH2. In an implementation, the channel pad 145 may be only at an upper end of the upper channel structure CH2, or the lower channel structure CH1 and the upper channel structure CH2 may each include the channel pad 145 and the channel pad 145 of the lower channel structure CH1 may be connected to the channel layer 140 of the upper channel structure CH2.

Each of the lower channel structure CH1 and the upper channel structure CH2 may have inclined side surfaces such that the channel structures may become narrower as it becomes closer to the substrate 101. In an implementation, a width of the uppermost portion of the lower channel structure CH1 may be greater than a width of the lowermost portion of the upper channel structure CH2. Accordingly, each of the channel structures CH may include a bent part formed due to a change in the width on a level of a region in which the lower channel structure CH1 and the upper channel structure CH2 are connected to each other.

The form of the stack structure GS and the plurality of channel structures CH described above may also be applied to example embodiments of FIGS. 1 to 4.

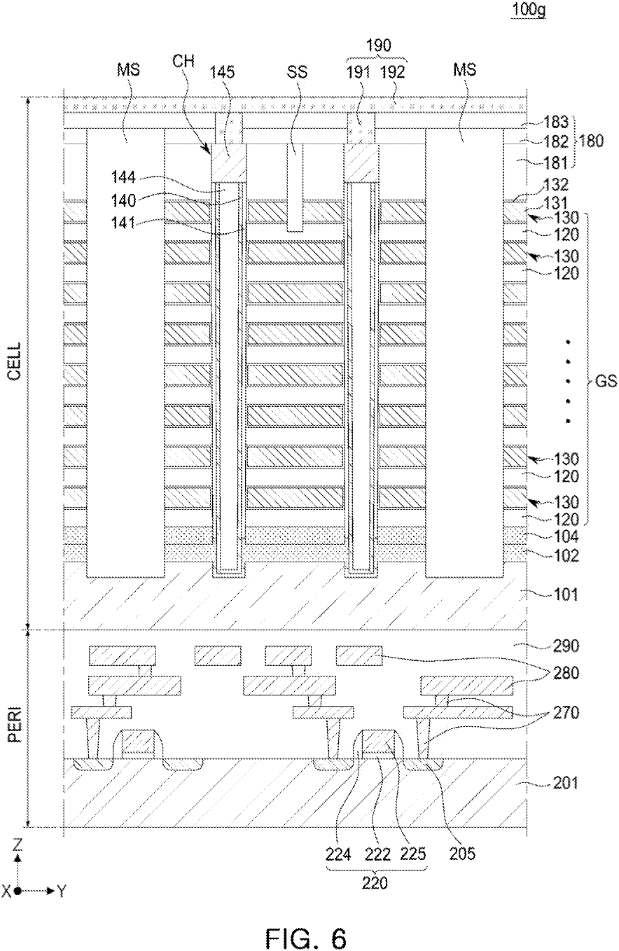

FIG. 6 is a cross-sectional view of a semiconductor device 100g according to example embodiments. FIG. 6 illustrates a region corresponding to a cross section of the semiconductor device 100g taken along line I-I′ of FIG. 1.

Referring to FIG. 6, the semiconductor device 100g may include a memory cell region CELL and a peripheral circuit region PERI that are vertically stacked. The memory cell region CELL may be on an upper end of the peripheral circuit region PERI. In an implementation, in a case of the semiconductor device 100 of FIG. 2, the peripheral circuit region PERI may be on the substrate 101 in a region that is not illustrated, or as in the semiconductor device 100g according to the present example embodiment, the peripheral circuit region PERI may be beneath the substrate 101. In an implementation, the memory cell region CELL may be on a lower end of the peripheral circuit region PERI. A description provided above with reference to FIGS. 1 to 5 may be equally applied to a description of the memory cell region CELL.

The peripheral circuit region PERI may include a base substrate 201 and circuit elements 220, circuit contact plugs 270, and circuit wiring lines 280 disposed on the base substrate 201.

The base substrate 201 may have an upper surface extending in the X-direction and the Y-direction. In the base substrate 201, separate element isolation layers may be formed, such that an active region may be defined. Source/drain regions 205 including impurities may be in a portion of the active region. The base substrate 201 may include a semiconductor material such as a group IV semiconductor, a group III-V compound semiconductor, or a group II-VI compound semiconductor. The base substrate 201 may also be provided as a bulk wafer or an epitaxial layer. In an implementation, the substrate 101 may be provided as a polycrystalline semiconductor layer such as a polycrystalline silicon layer or an epitaxial layer.

The circuit elements 220 may include horizontal transistors. Each of the circuit elements 220 may include a circuit gate dielectric layer 222, a spacer layer 224, and a circuit gate electrode 225. Source/drain regions 205 may be disposed in the base substrate 201 on both sides of the circuit gate electrode 225. The circuit elements 220 may be electrically connected to the gate layers 130 or the channel structures CH.

A peripheral region insulating layer 290 may be on the circuit elements 220 on the base substrate 201. The circuit contact plugs 270 may penetrate through the peripheral region insulating layer 290 and be connected to the source/drain regions 205. Electrical signals may be applied to the circuit elements 220 by the circuit contact plugs 270. In a region that is not illustrated, the circuit contact plugs 270 may also be connected to the circuit gate electrode 225. The circuit wiring lines 280 may be connected to the circuit contact plugs 270 and may be arranged as a plurality of layers.

In the semiconductor device 100g, the peripheral circuit region PERI may be first manufactured, and the substrate 101 of the memory cell region CELL may then be formed on the peripheral circuit region PERI, such that the memory cell region CELL may be manufactured. The substrate 101 may have the same size as the base substrate 201 or may be formed to be smaller than that of the base substrate 201. In an implementation, the lower structure may refer to a structure including the peripheral circuit region PERI and the substrate 101. The memory cell region CELL and the peripheral circuit region PERI may be connected to each other in a region that is not illustrated. In an implementation, one ends of the gate layers 130 in the Y-direction may be electrically connected to the circuit elements 220. The form in which the memory cell region CELL and the peripheral circuit region PERI are vertically stacked as described above may also be applied to example embodiments of FIGS. 1 to 5.

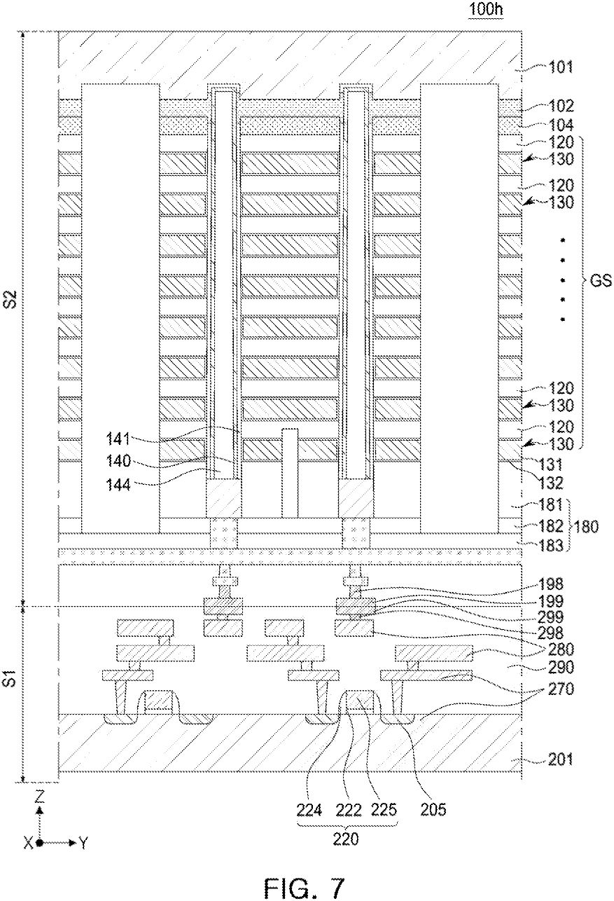

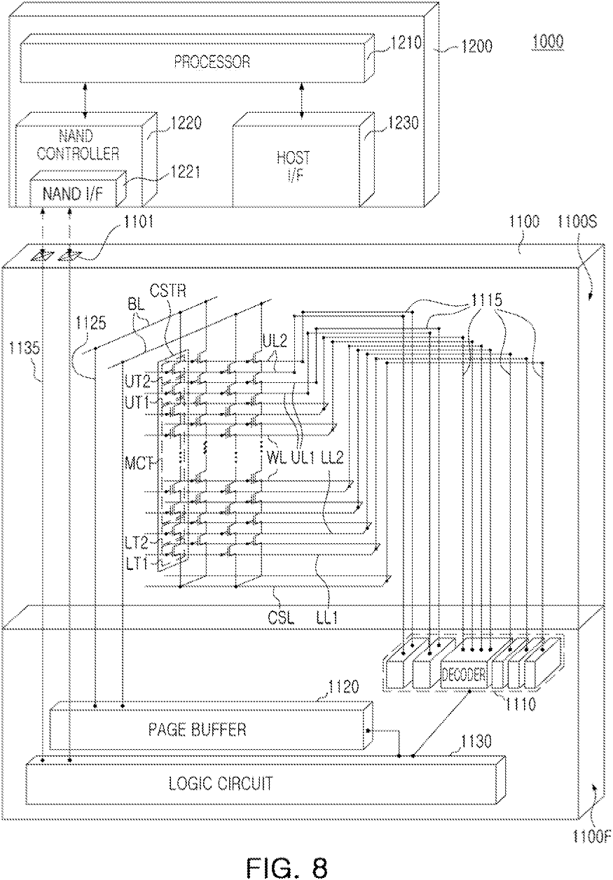

FIG. 7 is a cross-sectional view of a semiconductor device 100h according to example embodiments. FIG. 7 illustrates a region corresponding to a cross section of the semiconductor device 100h taken along line I-I′ of FIG. 1.

Referring to FIG. 7, the semiconductor device 100h may include a first structure S1 and a second structure S2 bonded to each other in a wafer bonding manner.

The description of the peripheral circuit region PERI described above with reference to FIG. 6 may be applied to the first structure S1. In an implementation, the first structure S1 may further include first bonding vias 298 and first bonding pads 299, which are bonding structures.

The first bonding vias 298 may be on the uppermost circuit wiring lines 280 and may be connected to the circuit wiring lines 280. At least some of the first bonding pads 299 may be connected to the first bonding vias 298 on the first bonding vias 298. The first bonding pads 299 may be connected to second bonding pads 199 of the second structure S2. The first bonding pads 299 may provide electrical connection paths according to bonding between the first structure S1 and the second structure S2, together with the second bonding pads 199. Each of the first bonding vias 298 and the first bonding pads 299 may include a conductive material such as copper (Cu).

The description provided above with reference to FIGS. 1 to 6 may be equally applied to the second structure S2, unless otherwise described. The second structure S2 may further include second bonding vias 198 and the second bonding pads 199, which are bonding structures. The second structure S2 may further include a protective layer covering an upper surface of the substrate 101.

The second bonding vias 198 and the second bonding pads 199 may be below the lowermost wiring lines. The second bonding vias 198 may be connected to the wiring lines and the second bonding pads 199, and the second bonding pads 199 may be bonded to the first bonding pads 299 of the first structure S1. Each of the second bonding vias 198 and the second bonding pads 199 may include a conductive material such as copper (Cu).

The first structure S1 and the second structure S2 may be bonded to each other by copper (Cu)-copper (Cu) bonding by the first bonding pads 299 and the second bonding pads 199. The first structure S1 and the second structure S2 may also be bonded to each other by dielectric-dielectric bonding, in addition to the copper (Cu)-copper (Cu) bonding. The dielectric-dielectric bonding may be bonding dielectric layers constituting a portion of each of the peripheral region insulating layer 290 and the upper insulating layer 180 and surrounding each of the first bonding pads 299 and the second bonding pads 199. Accordingly, the first structure S1 and the second structure S2 may be bonded to each other without a separate adhesive layer.

FIG. 8 is a schematic block diagram of a data storage system 1000 including a semiconductor device according to example embodiments.

Referring to FIG. 8, the data storage system 1000 may include a semiconductor device 1100 and a controller 1200 electrically connected to the semiconductor device 1100. The data storage system 1000 may be a storage device including one semiconductor device 1100 or a plurality of semiconductor devices 1100 or an electronic device including the storage device. In an implementation, the data storage system 1000 may be a solid state drive (SSD) device, a universal serial bus (USB), a computing system, a medical device, or a communications device including one semiconductor device 1100 or a plurality of semiconductor devices 1100.

The semiconductor device 1100 may be a nonvolatile memory device, and may be, e.g., the NAND flash memory device described above with reference to FIGS. 1 to 7. The semiconductor device 1100 may include a first semiconductor structure 1100F and a second semiconductor structure 1100S on the first semiconductor structure 1100F. In an implementation, the first semiconductor structure 1100F may be next to the second semiconductor structure 1100S. The first semiconductor structure 1100F may be a peripheral circuit structure including a decoder circuit 1110, a page buffer 1120, and a logic circuit 1130. The second semiconductor structure 1100S may be a memory cell structure including bit lines BL, a common source line CSL, word lines WL, first and second gate upper lines UL1 and UL2, first and second gate lower lines LL1 and LL2, and memory cell strings CSTR between the bit lines BL and the common source line CSL.

In the second semiconductor structure 1100S, each of the memory cell strings CSTR may include lower transistors LT1 and LT2 adjacent to the common source line CSL, upper transistors UT1 and UT2 adjacent to the bit lines BL, and a plurality of memory cell transistors MCT between the lower transistors LT1 and LT2 and the upper transistors UT1 and UT2. In an implementation, the number of lower transistors LT1 and LT2 and the number of upper transistors UT1 and UT2 may be variously modified.

In an implementation, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrode layers of the memory cell transistors MCT, and the gate upper lines UL1 and UL2 may be gate electrodes of the upper transistors UT1 and UT2, respectively.

In an implementation, the lower transistors LT1 and LT2 may include a lower erase control transistor LT1 and a ground select transistor LT2 connected to each other in series. The upper transistors UT1 and UT2 may include a string select transistor UT1 and an upper erase control transistor UT2 connected to each other in series. At least one of the lower erase control transistor LT1 and the upper erase control transistor UT1 may be used for an erase operation of erasing data stored in the memory cell transistors MCT using a gate induced drain leakage (GIDL) phenomenon.

The common source line CSL, the first and second gate lower lines LL1 and LL2, the word lines WL, and the first and second gate upper lines UL1 and UL2 may be electrically connected to the decoder circuit 1110 through first connection wirings 1115 extending from the first semiconductor structure 1100F to the second semiconductor structure 1100S. The bit lines BL may be electrically connected to the page buffer 1120 through second connection wirings 1125 extending from the first semiconductor structure 1100F to the second semiconductor structure 1100S.

In the first semiconductor structure 1100F, the decoder circuit 1110 and the page buffer 1120 may execute a control operation for at least one selection memory cell transistor of the plurality of memory cell transistors MCT. The decoder circuit 1110 and the page buffer 1120 may be controlled by the logic circuit 1130. The semiconductor device 1100 may communicate with the controller 1200 through input/output pads 1101 electrically connected to the logic circuit 1130. The input/output pads 1101 may be electrically connected to the logic circuit 1130 through input/output connection wirings 1135 extending from the first semiconductor structure 1100F to the second semiconductor structure 1100S.

The controller 1200 may include a processor 1210, a NAND controller 1220, and a host interface 1230. In an implementation, the data storage system 1000 may include a plurality of semiconductor devices 1100, and in this case, the controller 1200 may control the plurality of semiconductor devices 1100.

The processor 1210 may control a general operation of the data storage system 1000 including the controller 1200. The processor 1210 may operate according to predetermined firmware, and may access the semiconductor device 1100 by controlling the NAND controller 1220. The NAND controller 1220 may include a NAND interface 1221 processing communications with the semiconductor device 1100. A control command for controlling the semiconductor device 1100, data to be written to the memory cell transistors MCT of the semiconductor device 1100, data to be read from the memory cell transistors MCT of the semiconductor device 1100, and the like, may be transmitted through the NAND interface 1221. The host interface 1230 may provide a communications function between the data storage system 1000 and an external host. When a control command is received from the external host through the host interface 1230, the processor 1210 may control the semiconductor device 1100 in response to the control command.

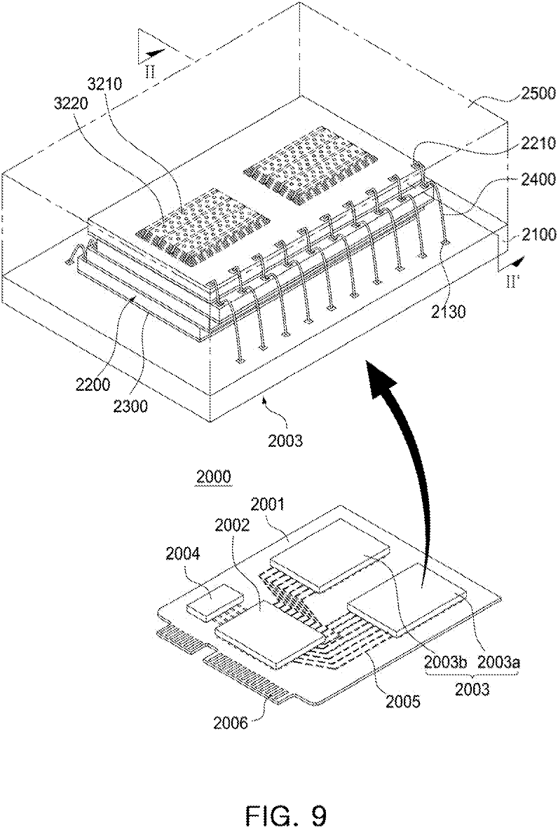

FIG. 9 is a schematic perspective view of a data storage system including a semiconductor device according to an example embodiment.

Referring to FIG. 9, a data storage system 2000 according to example embodiments may include a main board 2001 and a controller 2002, one or more semiconductor packages 2003, and a dynamic random access memory (DRAM) 2004 that are mounted on the main board 2001. The semiconductor package 2003 and the DRAM 2004 may be connected to the controller 2002 by wiring patterns 2005 formed on the main board 2001.

The main board 2001 may include a connector 2006 including a plurality of pins coupled to an external host. The number and arrangement of the plurality of pins in the connector 2006 may vary depending on a communications interface between the data storage system 2000 and the external host. In an implementation, the data storage system 2000 may communicate with the external host according to any one of interfaces such as universal serial bus (USB), peripheral component interconnect express (PCI-Express), serial advanced technology attachment (SATA), and M-PHY for universal flash storage (UFS). In an implementation, the data storage system 2000 may operate by power supplied from the external host through the connector 2006. The data storage system 2000 may further include a power management integrated circuit (PMIC) distributing the power supplied from the external host to the controller 2002 and the semiconductor package 2003.

The controller 2002 may write data to or read data from the semiconductor package 2003, and may improve an operation speed of the data storage system 2000.

The DRAM 2004 may be a buffer memory for alleviating a speed difference between the semiconductor package 2003, which is a data storage space, and the external host. The DRAM 2004 included in the data storage system 2000 may operate as a kind of cache memory, and may provide a space for temporarily storing data in a control operation for the semiconductor package 2003. When the data storage system 2000 includes the DRAM 2004, the controller 2002 may further include a DRAM controller for controlling the DRAM 2004, in addition to a NAND controller for controlling the semiconductor package 2003.

The semiconductor package 2003 may include first and second semiconductor packages 2003a and 2003b spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 on the package substrate 2100, adhesive layers 2300 on lower surfaces of the semiconductor chips 2200, connection structures 2400 electrically connecting the semiconductor chips 2200 to the package substrate 2100, and a molding layer 2500 covering the semiconductor chips 2200 and the connection structures 2400 on the package substrate 2100.

The package substrate 2100 may be a printed circuit board including package upper pads 2130. Each semiconductor chip 2200 may include input/output pads 2210. The input/output pads 2210 may correspond to the input/output pads 1101 of FIG. 8. Each of the semiconductor chips 2200 may include gate molded structures 3210 and channel structures 3220. Each of the semiconductor chips 2200 may include the semiconductor device described above with reference to FIGS. 1 to 7.

In an implementation, the connection structures 2400 may be bonding wires electrically connecting the input/output pads 2210 to the package upper pads 2130. Accordingly, in each of the first and second semiconductor packages 2003a and 2003b, the semiconductor chips 2200 may be electrically connected to each other in a bonding wire manner, and be electrically connected to the package upper pads 2130 of the package substrate 2100. In an implementation, in each of the first and second semiconductor packages 2003a and 2003b, the semiconductor chips 2200 may be electrically connected to each other by connection structures including through silicon vias (TSVs) instead of bonding wire-type connection structures 2400.

In an implementation, the controller 2002 and the semiconductor chips 2200 may be included in one package. In an implementation, the controller 2002 and the semiconductor chips 2200 may be mounted on a separate interposer substrate different from the main board 2001, and the controller 2002 and the semiconductor chips 2200 may be connected to each other by wirings formed on the interposer substrate.

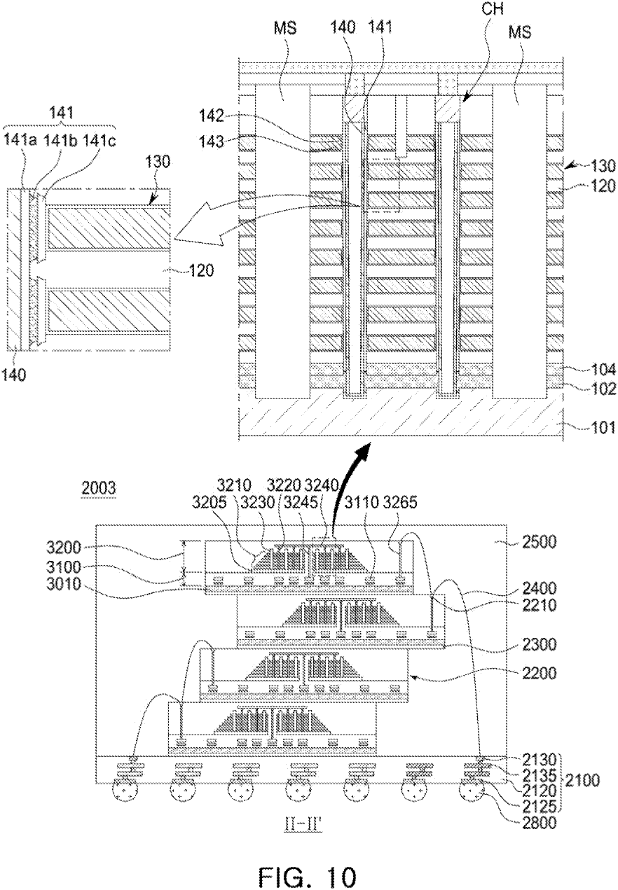

FIG. 10 is a schematic cross-sectional view of a semiconductor package according to an example embodiment. FIG. 10 illustrates an example embodiment of the semiconductor package 2003 of FIG. 9, and conceptually illustrates a region of the semiconductor package 2003 taken along line II-II′ of FIG. 9.

Referring to FIG. 10, in the semiconductor package 2003, the package substrate 2100 may be a printed circuit board. The package substrate 2100 may include a package substrate body part 2120, package upper pads 2130 (see FIG. 9) on an upper surface of the package substrate body part 2120, package lower pads 2125 on or exposed through a lower surface of the package substrate body part 2120, and internal wirings 2135 electrically connecting the package upper pads 2130 and the package lower pads 2125 to each other in the package substrate body part 2120. The package upper pads 2130 may be electrically connected to the connection structures 2400. The package lower pads 2125 may be connected to the wiring patterns 2005 of the main board 2001 of the data storage system 2000 as illustrated in FIG. 9 through conductive connection parts 2800.

Each of the semiconductor chips 2200 may include a semiconductor substrate 3010 and a first semiconductor structure 3100 and a second semiconductor structure 3200 that are sequentially stacked on the semiconductor substrate 3010. The first semiconductor structure 3100 may include a peripheral circuit region including peripheral wirings 3110. The second semiconductor structure 3200 may include a common source line 3205, a gate molded structure 3210 on the common source line 3205, channel structures 3220 and isolation regions 3230 penetrating through the gate molded structure 3210, bit lines 3240 electrically connected to the channel structures 3220, and cell contact plugs electrically connected to word lines WL (see FIG. 8) of the gate molded structure 3210. As described above with reference to FIGS. 1 to 7, each of the semiconductor chips 2200 may include channel structures CH including a charge storage pattern 141b and a blocking pattern 141c.

Each of the semiconductor chips 2200 may include through wirings 3245 electrically connected to the peripheral wirings 3110 of the first semiconductor structure 3100 and extending into the second semiconductor structure 3200. The through wiring 3245 may be outside the gate molded structure 3210, and may penetrate through the gate molded structure 3210. Each of the semiconductor chips 2200 may further include input/output pads 2210 (see FIG. 9) electrically connected to the peripheral wirings 3110 of the first semiconductor structure 3100.

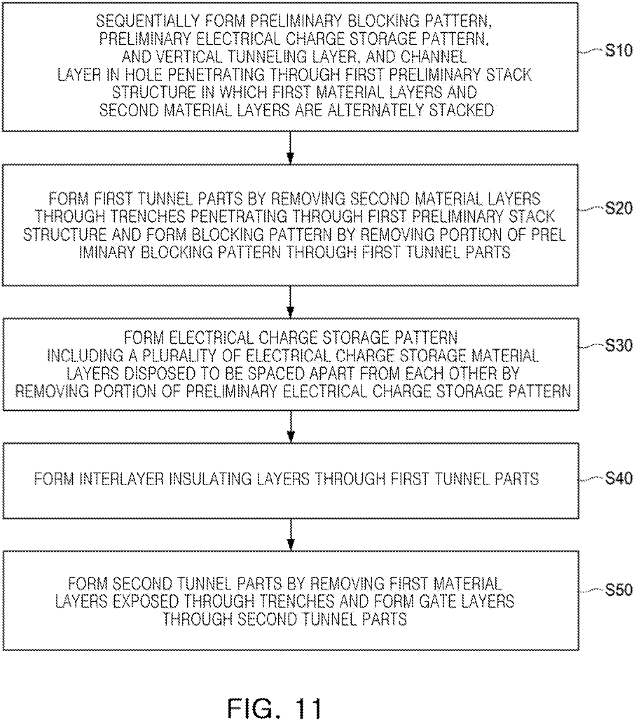

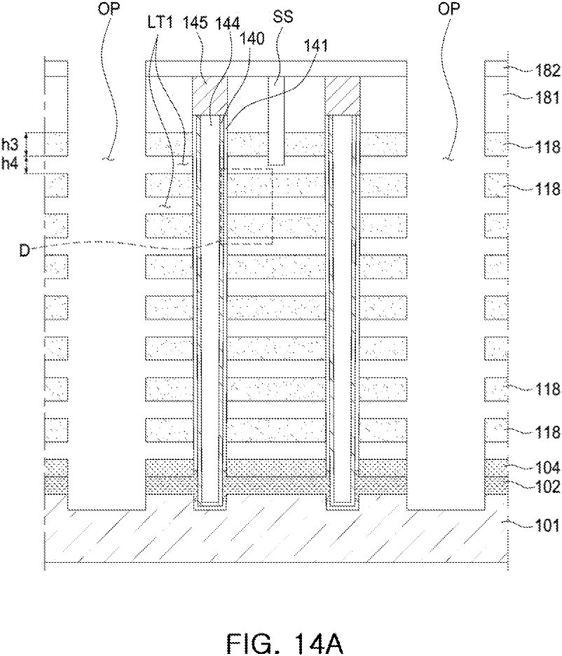

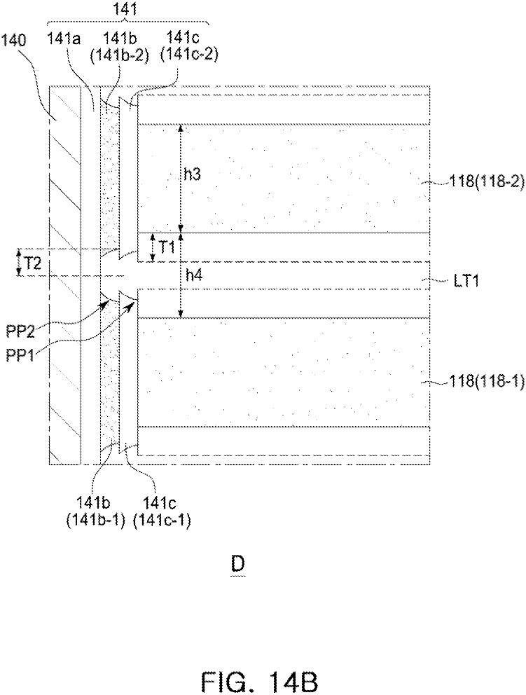

FIG. 11 is a flowchart of a process sequence of a method of manufacturing a semiconductor device 100 according to example embodiments. FIGS. 12A to 16 are cross-sectional views of stages in a method of manufacturing a semiconductor device 100 according to example embodiments. FIGS. 12A, 13A, 14A, 15, and 16 illustrate a region corresponding to FIG. 2, FIG. 12B illustrates a region corresponding to region ‘B’ of FIG. 12A, FIG. 13B illustrates a region corresponding to region ‘C’ of FIG. 13A, and FIG. 14B illustrates a region corresponding to region ‘D’ of FIG. 14A.

Referring to FIGS. 11, 12A, and 12B, horizontal insulating layers 110 and a second horizontal conductive layer 104 may be sequentially formed on a substrate 101, a first preliminary stack structure GS′ may be formed by alternately stacking first material layers 118 and second material layers 120, and a preliminary channel dielectric layer 141′ including a preliminary blocking pattern 141c, a preliminary charge storage pattern 141b, and a vertical tunneling layer 141a, a channel layer 140, a channel filling insulating layer 144, and a channel pad 145 may be sequentially formed in a hole penetrating through the first preliminary stack structure GS′ (S10).

First, the horizontal insulating layers 110 and the second horizontal conductive layer 104 may be formed on the substrate 101. The horizontal insulating layers 110 may include first to third horizontal insulating layers, and the first horizontal insulating layer and the third horizontal insulating layer may include the same material. The first horizontal insulating layer and the second horizontal insulating layer may include different materials. In an implementation, the first horizontal insulating layer and the third horizontal insulating layer may be formed of the same material as the interlayer insulating layers 120, and the second horizontal insulating layer may be formed of the same material as the first material layers 118. The horizontal insulating layers 110 may be layers of which some are replaced with the first horizontal conductive layer 102 (see FIG. 2) through a subsequent process. The lower structure may include the substrate 101, the horizontal insulating layers 110, and the second horizontal conductive layer 104.

Next, the first preliminary stack structure GS′ including the first material layers 118 and the second material layers 119 alternately stacked in the Z-direction on the lower structure may be formed. In an implementation, the first preliminary stack structure GS′ may also be referred to as a molded structure. The first material layers 118 may be layers, at least some of which will be replaced by the gate layers 130 (see FIG. 2) through a subsequent process. The first material layers 118 may be formed of a material different from that of the second material layers 119, and may be formed of a material that may be etched with etching selectivity with respect to the second material layers 119 under a specific etching condition. In an implementation, the first material layers 118 may include, e.g., a nitride, a silicon nitride, or a nitride material, and the second material layers 119 may include, e.g., silicon. The silicon may be, e.g., polysilicon. In an implementation, each of the first material layers 118 may have a first thickness h1 (e.g., in the Z direction), each of the second material layers 119 may have a second thickness h2, and the first thickness h1 may be greater than the second thickness h2. In example embodiments, the thicknesses of each of the first material layers 118 and the second material layers 119 may not all be the same as each other. In an implementation, the thicknesses of the first material layers 118 and the second material layers 119 and the number of films constituting the first material layers 118 and the second material layers 119 may be variously modified.

Next, a first upper insulating layer 181 covering the first preliminary stack structure GS′ on the substrate 101 may be formed, and a hole penetrating through the first upper insulating layer 181 and the molded structure GS′ may be formed. The hole may penetrate through the second horizontal conductive layer 104 and the horizontal insulating layers 110 together with the first preliminary stack structure GS′ and extend into the substrate 101. In an implementation, the hole may not penetrate through the substrate 101, and may be in contact with an upper surface of the substrate 101. In an implementation, the hole may have a pillar shape having inclined side surfaces.

Next, the preliminary channel dielectric layer 141′, the channel layer 140, the channel filling insulating layer 144, and the channel pad 145 may be sequentially formed in the hole. The preliminary channel dielectric layer 141′ may be formed to have a uniform thickness by conformally covering an inner portion of the hole sequentially with the preliminary blocking pattern 141c′, the preliminary charge storage pattern 141b′, and the vertical tunneling layer 141a. The channel layer 140 may be formed on the preliminary channel dielectric layer 141′, and the channel filling insulating layer 144 may be formed to fill a space between the channel layers 140 and may be formed of an insulating material. In an implementation, the channel filling insulating layer 144 may fill the space between the channel layers 140 with a conductive material. The channel pad 145 may be made of a conductive material such as polycrystalline silicon. The preliminary charge storage pattern 141b′ may include, e.g., a nitride, a silicon nitride, or a nitride material. The preliminary charge storage pattern 141b′ may be etched together with the first material layers 118 under a specific etching condition, and may have an etch rate slower than that of the first material layers 118 under the specific etching condition. The preliminary charge storage pattern 141b′ may include the same material as the first material layers 118, and may have a composition ratio different from that of the first material layers 118.

Referring to FIGS. 11, 13A, and 13B, trenches OP penetrating through the first preliminary stack structure GS′ may be formed, first tunnel parts LT1 may be formed by removing the second material layers 119 through the trenches OP, and the blocking pattern 141c may be formed by removing at least a portion of the preliminary blocking pattern 141c′ through the first tunnel parts LT1 (S20).

First, a second upper insulating layer 182 covering the first upper insulating layer 181 and the channel pad 145 may be formed, and the trenches OP penetrating through the first preliminary stack structure GS′ and the first and second upper insulating layers 181 and 182 may be formed in regions corresponding to the isolation structures MS (see FIGS. 1 and 2). The trenches OP may be formed to penetrate through the second horizontal conductive layer 104 and to extend in the X-direction.

In an implementation, the second horizontal insulating layer may be exposed by an etch-back process while forming separate sacrificial spacer layers in the trenches OP, through which the horizontal insulating layer 110 may be removed. In a process of removing the horizontal insulating layer 110, a portion of the vertical tunneling layer 141a exposed in a region from which the horizontal insulating layers 110 are removed may also be removed together with the horizontal insulating layer 110. The first horizontal conductive layer 102 may be formed by depositing a conductive material in the region in the horizontal insulating layer 110 has been removed, and the sacrificial spacer layers may then be removed in the trenches OP.

Next, the first tunnel parts LT1 may be formed by removing the second material layers 119 exposed through the trenches OP. The second material layers 119 may be selectively etched with respect to the first material layers 118 under a specific etching condition. The second material layers 119 may be removed through, e.g., a wet etching process. A thickness of each of the first tunnel parts LT1 may be substantially the same as the second thickness h2 of each of the second material layers 119.

Next, the blocking pattern 141c may be formed by removing at least a portion of the preliminary blocking pattern 141c′ exposed through the first tunnel parts LT1. The blocking pattern 141c, including a plurality of blocking material layers 141c-1 and 141c-2 spaced apart from each other in the Z-direction, may be formed through a wet etching process for the preliminary blocking pattern 141c′.

Referring to FIGS. 11, 14A, and 14B, the charge storage pattern 141b including the plurality of charge storage material layers 141b-1 and 141b-2 spaced apart from each other in the Z-direction may be formed by removing at least a portion of the preliminary charge storage pattern 141b′ exposed by the removed preliminary blocking pattern 141c′ (S30).

A portion of the preliminary charge storage pattern 141b′ may be removed by an etching process such as a wet etching process. The etching process may include a process of removing portions of the first material layers 118 together with a portion of the preliminary charge storage pattern 141b.′ In an implementation, the etching process may be a process of selectively etching the preliminary charge storage pattern 141b′ and the first material layers 118 with respect to the blocking pattern 141c. Accordingly, a third thickness h3 of each of the first material layers 118 remaining through or after the etching process may be smaller than the existing first thickness h1 (see FIGS. 12A and 12B) and a fourth thickness h4 of each of the expanded first tunnel parts LT1 may be greater than the second thickness h2 (see FIGS. 12A and 12B) of each of the second material layers 119. The first material layers 118 may include a material having an etch rate faster than that the preliminary charge storage pattern 141b′ in the etching process. Accordingly, a thickness T1 of the material of the first material layers 118 removed in the vertical direction may be greater than a thickness T2 of the material of the preliminary charge storage pattern 141b′ removed in the vertical direction. In an implementation, the third thickness h3 of each of the first material layers 118 remaining through or after the etching process may be smaller than a length of each of the plurality of charge storage material layers 141b-1 and 141b-2 in the Z-direction.

The charge storage pattern 141b may be formed by partially removing the preliminary charge storage pattern 141b′, such that the channel dielectric layer 141 including the vertical tunneling layer 141a, the charge storage pattern 141b, and the blocking pattern 141c may be formed.

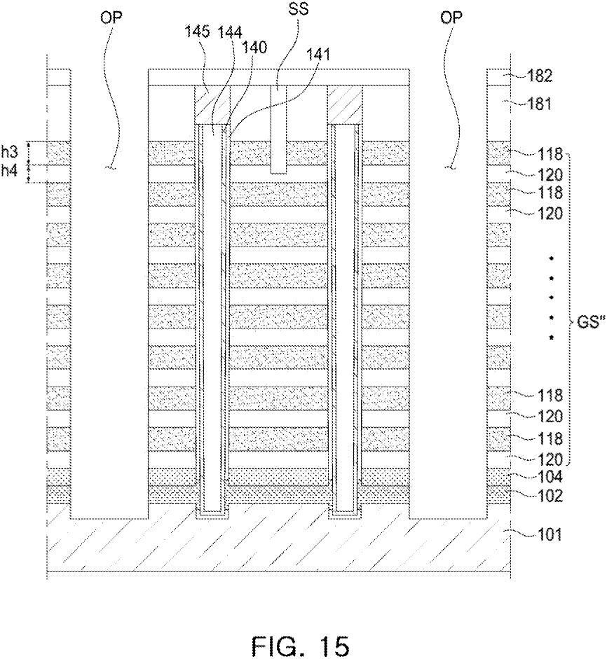

Referring to FIGS. 11 and 15, interlayer insulating layers 120 may be formed through the first tunnel parts LT1 (S40).

The interlayer insulating layers 120 may be formed by filling insulating materials between the first material layers 118, between the plurality of charge storage material layers 141b-1 and 141b-2, and between the plurality of blocking material layers 141c-1 and 141c-2 through the trenches OP and the first tunnel parts LT1 and removing the insulating materials filled in the trenches OP. Accordingly, a second preliminary stack structure GS” in which the interlayer insulating layers 120 and the first material layers are alternately stacked may be formed. The interlayer insulating layers 120 may include, e.g., an oxide, a silicon oxide, or an oxide material.

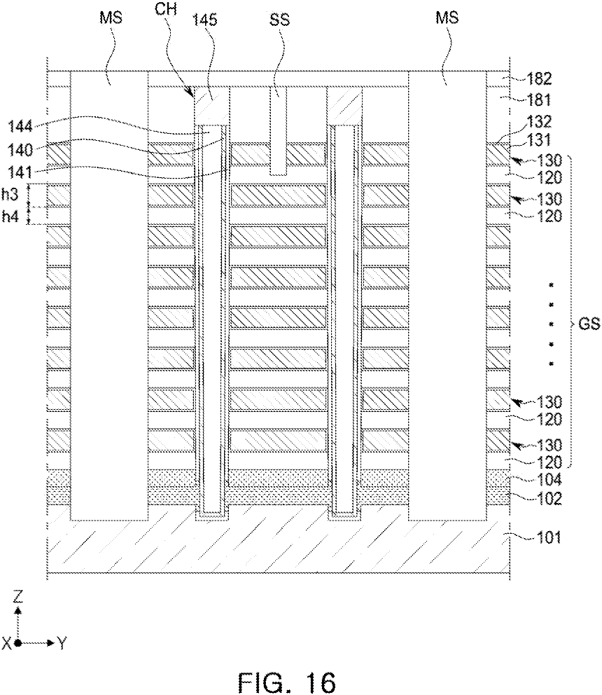

Referring to FIGS. 11 and 16, gate layers 130 may be formed through second tunnel parts formed by selectively removing the first material layers 118 exposed through the trenches OP (S50).

The first material layers 118 may be selectively removed with respect to the interlayer insulating layers 120 using, e.g., a wet etching process. Accordingly, the second tunnel parts may be formed between the interlayer insulating layers 120. Gate dielectric layers 132 may be formed by depositing dielectric materials having a uniform thickness while covering the interlayer insulating layers 120 and the blocking pattern 141c in the second tunnel parts, and gate conductive layers 131 may be formed by filling conductive materials between the gate dielectric layers 132. The conductive material may include a metal, polycrystalline silicon, or a metal silicide material. Accordingly, a stack structure GS in which the gate layers 130 respectively including the gate dielectric layer 132 and the gate conductive layer 131 and the interlayer insulating layers 120 are alternately stacked may be formed.

Next, isolation structures MS may be formed by removing the dielectric materials and the conductive materials deposited in the trenches OP through an additional process and then filling insulating materials in the trenches OP.

Next, the semiconductor device 100 of FIG. 2 may be formed by forming a third upper insulating layer 183 (see FIG. 2) covering the isolation structures MS and the second upper insulating layer 182 and forming upper contact structures 191 penetrating through the second and third upper insulating layers 182 and 183 and in contact with the channel pads 145 and upper wiring patterns 192 on the upper contact structures 191.

By way of summation and review, increasing a data storage capacity of a semiconductor device has been considered. For example, a semiconductor device may include three-dimensionally arranged memory cells instead of two-dimensionally arranged memory cells.

The semiconductor device according to an embodiment may exhibit improved electrical characteristics, e.g., because a thickness of each of the plurality of charge storage material layers spaced apart from each other may be relatively greater than the thickness of each of the gate layers.

One or more embodiments may provide a semiconductor device of which electrical characteristics are improved.

One or more embodiments may provide a method of manufacturing a semiconductor device of which electrical characteristics are improved.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A semiconductor device, comprising:
a lower structure including a substrate;
a stack structure including a first gate layer, a first interlayer insulating layer, and a second gate layer sequentially stacked on the lower structure; and
a channel structure penetrating through the stack structure and in contact with the lower structure, the channel structure including a channel layer, a vertical tunneling layer surrounding the channel layer, a charge storage pattern on an outer side surface of the vertical tunneling layer, and a blocking pattern on an outer side surface of the charge storage pattern, wherein:
the charge storage pattern includes a first charge storage material layer and a second charge storage material layer spaced apart from each other in a vertical direction of an upper surface of the substrate and adjacent to the first gate layer and the second gate layer, respectively,
the blocking pattern includes a first blocking material layer between the first charge storage material layer and the first gate layer and a second blocking material layer spaced apart from the first blocking material layer in the vertical direction and between the second charge storage material layer and the second gate layer, and
the blocking pattern is in contact with the outer side surface of the charge storage pattern and includes a vertical protrusion part extending longer than the outer side surface of the charge storage pattern in the vertical direction.

2. The semiconductor device as claimed in claim 1, wherein:
a length of the first charge storage material layer in the vertical direction is greater than a length of the first gate layer in the vertical direction, and
a length of the second charge storage material layer in the vertical direction is greater than a length of the second gate layer in the vertical direction.

3. The semiconductor device as claimed in claim 1, wherein:
the first interlayer insulating layer includes:
a first horizontal protrusion part extending in a direction from a space between the first gate layer and the second gate layer toward the vertical tunneling layer, and
a second horizontal protrusion part extending in a direction from the first horizontal protrusion part toward the vertical tunneling layer,
the first horizontal protrusion part isolates the first blocking material layer and the second blocking material layer from each other, and
the second horizontal protrusion part isolates the first charge storage material layer and the second charge storage material layer from each other.

4. The semiconductor device as claimed in claim 3, wherein each of the first and second horizontal protrusion parts has a convex shape protruding in the direction toward the vertical tunneling layer.

5. The semiconductor device as claimed in claim 3, wherein portions of the vertical protrusion parts of the first and second blocking material layers are in contact with the first and second horizontal protrusion parts of the first interlayer insulating layer.

6. The semiconductor device as claimed in claim 5, wherein a maximum length of the first horizontal protrusion part in the vertical direction is smaller than a maximum length of the second horizontal protrusion part in the vertical direction.

7. The semiconductor device as claimed in claim 1, wherein upper surfaces and lower surfaces of each of the first charge storage material layer, the second charge storage material layer, the first blocking material layer, and the second blocking material layer are curved surfaces.

8. The semiconductor device as claimed in claim 7, wherein the upper surfaces and the lower surfaces of the first charge storage material layer and the second charge storage material layer are convex toward an inner portion of the first charge storage material layer and the second charge storage material layer, respectively.

9. The semiconductor device as claimed in claim 1, wherein each of the first and second gate layers has a greater thickness in the vertical direction in a region in contact with the blocking pattern than in other regions distal to the blocking pattern.

10. The semiconductor device as claimed in claim 1, wherein each of the vertical tunneling layer, the charge storage pattern, and the blocking pattern has a uniform thickness in a horizontal direction perpendicular to the vertical direction.

11. The semiconductor device as claimed in claim 1, wherein:
the lower structure further includes a first horizontal conductive layer and a second horizontal conductive layer sequentially on the substrate,
the channel structure penetrates through the first horizontal conductive layer and the second horizontal conductive layer and is in contact with the substrate, and
the first horizontal conductive layer penetrates through the vertical tunneling layer and is in contact with the channel layer.

12. A semiconductor device, comprising:
a substrate;
gate layers stacked on the substrate, the gate layers being spaced apart from each other in a vertical direction of an upper surface of the substrate; and
channel structures penetrating through the gate layers and extending in the vertical direction, the channel structures respectively including a channel layer and a channel dielectric layer covering an outer side surface and a lower surface of the channel layer, wherein:
the channel dielectric layer includes a vertical tunneling layer, a charge storage pattern, and a blocking pattern sequentially stacked on the outer side surface and the lower surface of the channel layer,
the charge storage pattern includes a first charge storage material layer and a second charge storage material layer on an outer side surface of the vertical tunneling layer and spaced apart from each other in the vertical direction, each of the first and second charge storage material layers including a first side surface in contact with the outer side surface of the vertical tunneling layer and a second side surface opposing the first side surface,
the blocking pattern includes a first blocking material layer on the second side surface of the first charge storage material layer and a second blocking material layer spaced apart from the first blocking material layer in the vertical direction and on the second surface of the second charge storage material layer,
each of the first and second blocking material layers includes a third side surface in contact with the charge storage pattern and a fourth side surface opposing the third side surface,
a first length of the first side surface in the vertical direction is greater than a thickness, in the vertical direction, of each of the gate layers, and
a second length of the second side surface in the vertical direction and a third length of the third side surface in the vertical direction are different from each other.

13. The semiconductor device as claimed in claim 12, wherein the channel dielectric layer includes a step between the charge storage pattern and the blocking pattern.

14. The semiconductor device as claimed in claim 12, wherein the second length is smaller than the third length.

15. The semiconductor device as claimed in claim 14, wherein:
the first length is greater than the second length, and
the third length is greater than a fourth length of the fourth side surface in the vertical direction.

16. The semiconductor device as claimed in claim 12, further comprising interlayer insulating layers on the substrate, the interlayer insulating layers being spaced apart from each other in the vertical direction and stacked alternately with the gate layers,
wherein: the gate layers include a first gate layer in contact with the first blocking material layer and a second gate layer adjacent to the first gate layer and in contact with the second blocking material layer, and
the interlayer insulating layers include a first interlayer insulating layer between the first gate layer and the second gate layer.

17. The semiconductor device as claimed in claim 16, wherein the first interlayer insulating layer extends between the first gate layer and the second gate layer to cover the first and second charge storage material layers, and is in contact with the vertical tunneling layer.

18. The semiconductor device as claimed in claim 12, wherein the first length is smaller than the third length.

19. A data storage system, comprising:
a semiconductor storage device including a lower structure including a lower substrate, circuit elements on the lower substrate, and an upper substrate on the circuit elements; a stack structure including a first gate layer, a first interlayer insulating layer, and a second gate layer sequentially stacked on the lower structure; a channel structure penetrating through the stack structure and in contact with the lower structure, and including a channel layer, a vertical tunneling layer surrounding the channel layer, an charge storage pattern on an outer side surface of the vertical tunneling layer, and a blocking pattern on an outer side surface of the charge storage pattern; and an input/output pad electrically connected to the circuit elements, the charge storage pattern including first and second charge storage material layers spaced apart from each other in a vertical direction of an upper surface of the lower structure and adjacent to the first and second gate layers, respectively, the blocking pattern including a first blocking material layer in contact with the first charge storage material layer and the first gate layer and a second blocking material layer spaced apart from the first blocking material layer in the vertical direction and in contact with the second charge storage material layer and the second gate layer, and the blocking pattern being in contact with the outer side surface of the charge storage pattern and including vertical protrusion part extending to be longer than the outer side surface of the charge storage pattern in the vertical direction; and
a controller electrically connected to the semiconductor storage device through the input/output pads and controlling the semiconductor storage device.

20. The data storage system as claimed in claim 19, wherein, in the semiconductor storage device, a distance between the spaced apart first and second charge storage material layers is smaller than a distance between the spaced apart first and second gate layers.

21-26. (canceled)
